(19) United States
(12) Patent Application Publication
(10) Pub. No.: US 2023/0097629 A1
(43) Pub. Date: Mar. 30, 2023

(54) SEMICONDUCTOR DEVICE

(71) Applicant: ROHM CO., LTD., Kyoto-shi, Kyoto (JP)

(72) Inventor: Yuki NAKANO, Kyoto-shi, Kyoto (JP)

(73) Assignee: ROHM CO., LTD., Kyoto-shi, Kyoto (JP)

(21) Appl. No.: 17/911,426

(22) PCT Filed: Jun. 18, 2021
(86) PCT No.: PCT/JP2021/023202

§ 371 Date: Sep. 14, 2022

(30) Foreign Application Priority Data
Jun. 26, 2020 (JP) 2020-110900

(51) Int. Cl. H01L 29/78; H01L 29/06; H01L 29/16; H01L 29/08; H01L 29/10; H01L 29/423

(52) U.S. Cl. CPC H01L 29/7813; H01L 29/0696; H01L 29/1608; H01L 29/0878; H01L 29/1095; H01L 29/4238

(57) ABSTRACT

A semiconductor device includes a semiconductor chip having a principal surface, a first-conductivity-type drift region, a second-conductivity-type body region, a first-conductivity-type source region, a plurality of trench source structures that are formed at the principal surface so as to cross the source region and the body region and so as to reach the drift region and that are arranged with intervals therebetween in a first direction, a second-conductivity-type body connection region formed in a region between two of the trench source structures that are adjacent in the surface layer portion of the body region so as to be electrically connected to the body region, and a first-conductivity-type source connection region formed in a region between two of the trench source structures that are adjacent in a region differing from the body connection region in the surface layer portion of body region so as to be electrically connected to source region.

### TECHNICAL FIELD

This application corresponds to Japanese Patent Application No. 2020-110900 filed in the Japan Patent Office on Jun. 26, 2020, the entire disclosure of which is incorporated herein by reference. The present invention relates to a semiconductor device.

### BACKGROUND ART

Patent Literature 1 discloses a semiconductor device provided with a semiconductor substrate, an n type drift region, a p type body region, a plurality of trench gate structures, a plurality of trench source structures, a plurality of n type source regions, and a plurality of p type body contact regions. The drift region is formed at a surface layer portion of the semiconductor substrate. The body region is formed at a surface layer portion of the drift region. The plurality of trench gate structures are formed at the semiconductor substrate with intervals therebetween so as to reach the drift region, and are arranged in a stripe shape extending in one direction.

The plurality of trench source structures are each formed in a region between two adjacent trench gate structures in the semiconductor substrate, and are arranged in a stripe shape extending along the trench gate structure. Each of the source regions is formed along each of the trench gate structures in a surface layer portion of the body region. Each of the body contact regions is formed along each of the trench source structures in the surface layer portion of the body region, and is connected to each of the source regions.

### CITATION LIST

### Patent Literature

Patent Literature 1: United States Patent Application Publication No. 2017/0040423

### SUMMARY OF INVENTION

### Technical Problem

One preferred embodiment of the present invention provides a semiconductor device capable of contributing to miniaturization.

### Solution to Problem

One preferred embodiment of the present invention provides a semiconductor device including a semiconductor chip having a principal surface, a first-conductivity-type drift region formed at a surface layer portion of the principal surface, a second-conductivity-type body region formed at a surface layer portion of the drift region, a first-conductivity-type source region formed at a surface layer portion of the body region, a plurality of trench source structures that are formed at the principal surface so as to cross the source region and the body region and so as to reach the drift region and that are arranged with intervals therebetween in a first direction, a second-conductivity-type body connection region formed in a region between two of the trench source structures that are adjacent in the surface layer portion of the body region so as to be electrically connected to the body region, and a first-conductivity-type source connection region formed in a region between two of the trench source structures that are adjacent in a region differing from the body connection region in the surface layer portion of the body region so as to be electrically connected to the source region.

The aforementioned or still other objects, features, and effects of the present invention will be clarified by the following description of preferred embodiments given below with reference to the accompanying drawings.

### BRIEF DESCRIPTION OF DRAWINGS

FIG. 1 is a plan view showing a SiC semiconductor device according to a first preferred embodiment of the present invention.

FIG. 2 is a plan view showing a layout of an electrode shown in FIG. 1.

FIG. 3 is a plan view showing a layout of a first principal surface of a SiC chip shown in FIG. 1.

FIG. 4 is a plan view in which a main portion of a structure shown in FIG. 3 is enlarged.

FIG. 5 is a plan view in which another main portion of the structure shown in FIG. 3 is enlarged.

FIG. 6 is a cross-sectional view along line VI-VI shown in FIG. 4.

FIG. 7 is a cross-sectional view along line VII-VII shown in FIG. 4.

FIG. 8 is a cross-sectional view along line VIII-VIII shown in FIG. 4.

FIG. 9 is a cross-sectional view along line IX-IX shown in FIG. 4.

FIG. 10 is a cross-sectional view along line X-X shown in FIG. 5.

FIG. 11 corresponds to FIG. 4, and is a plan view shown to describe a structure of a SiC semiconductor device according to a second preferred embodiment of the present invention.

FIG. 12 corresponds to FIG. 4, and is a plan view shown to describe a structure of a SiC semiconductor device according to a third preferred embodiment of the present invention.

FIG. 13 corresponds to FIG. 4, and is a plan view shown to describe a structure of a SiC semiconductor device according to a fourth preferred embodiment of the present invention.

FIG. 14 corresponds to FIG. 4, and is a plan view shown to describe a structure of a SiC semiconductor device according to a fifth preferred embodiment of the present invention.

FIG. 15 corresponds to FIG. 4, and is a plan view shown to describe a structure of a SiC semiconductor device according to a sixth preferred embodiment of the present invention.

FIG. 16 is a cross-sectional view along line XVI-XVI shown in FIG. 15.

FIG. 17 corresponds to FIG. 6, and is a cross-sectional view shown to describe a structure of a SiC semiconductor device according to a seventh preferred embodiment of the present invention.

FIG. 18 corresponds to FIG. 6, and is a cross-sectional view shown to describe a structure of a SiC semiconductor device according to an eighth preferred embodiment of the present invention.

### DESCRIPTION OF EMBODIMENTS

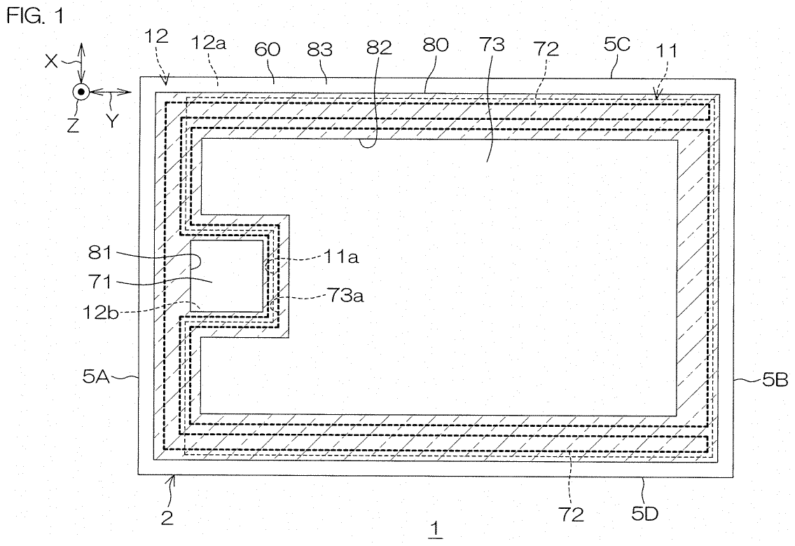

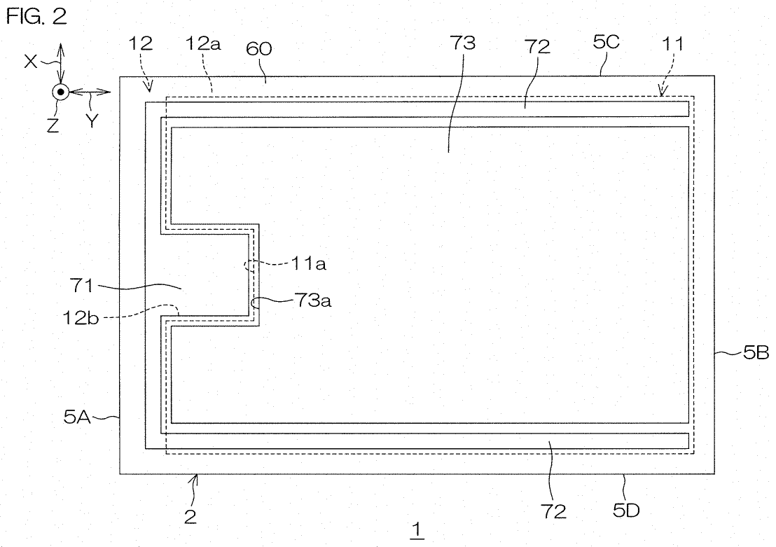

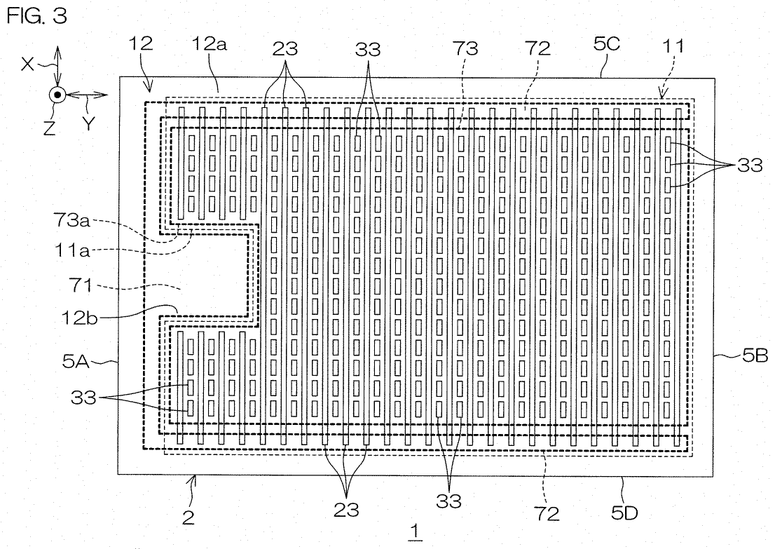

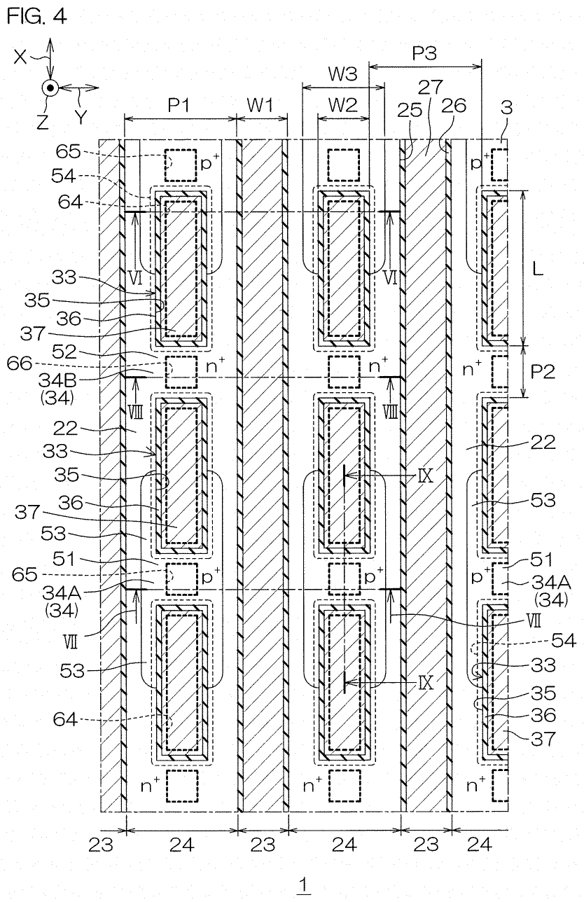

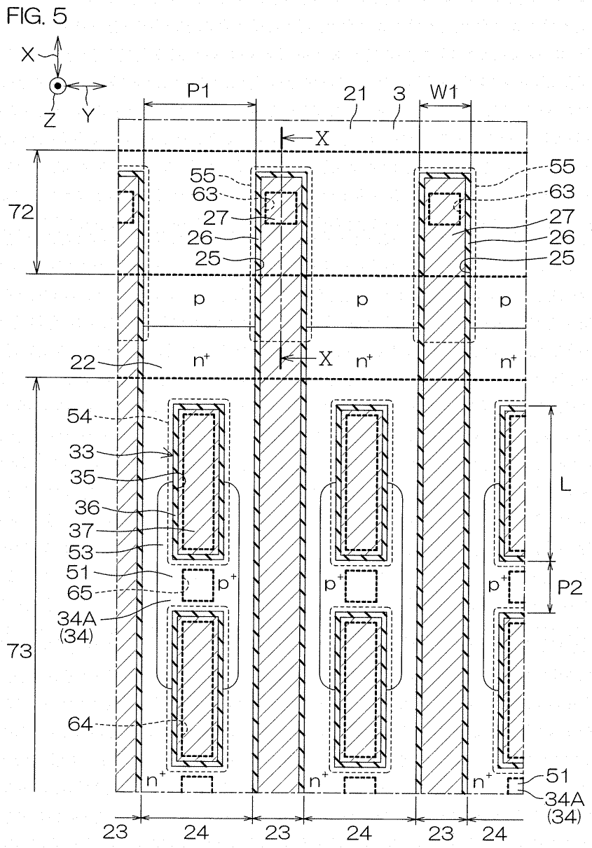

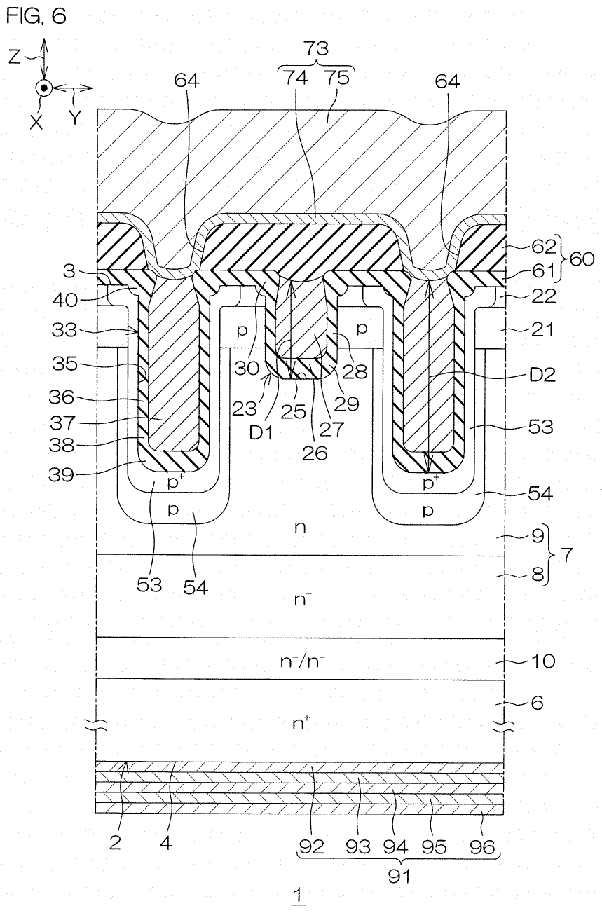

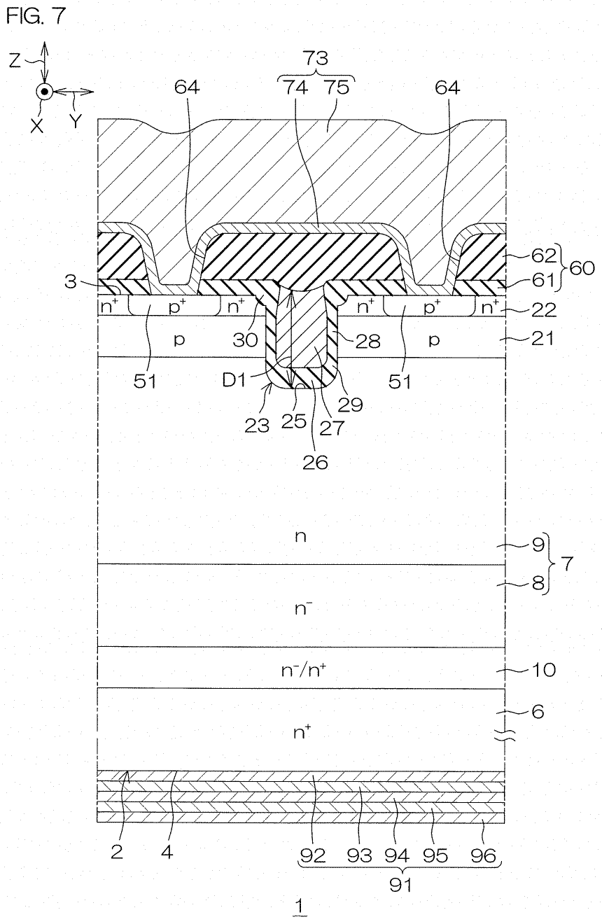

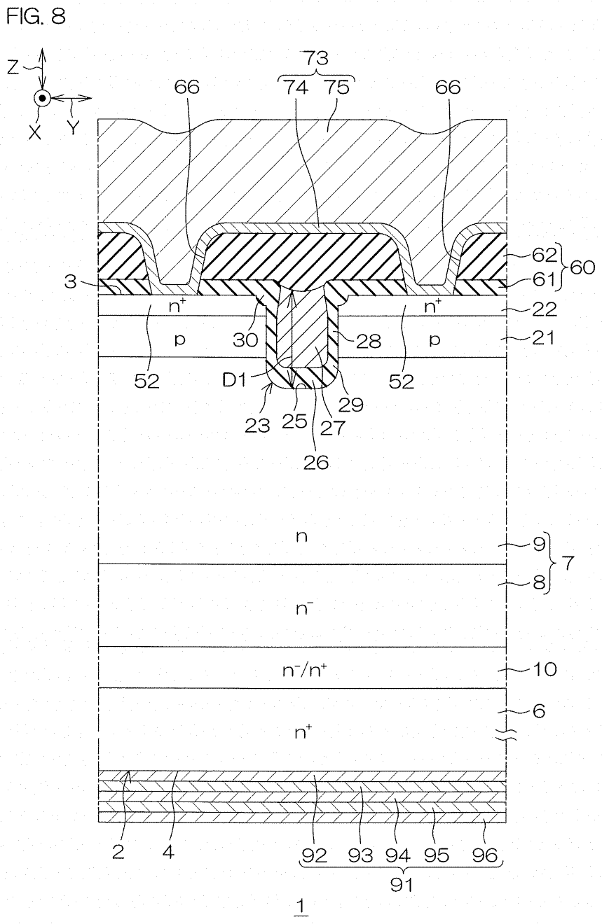

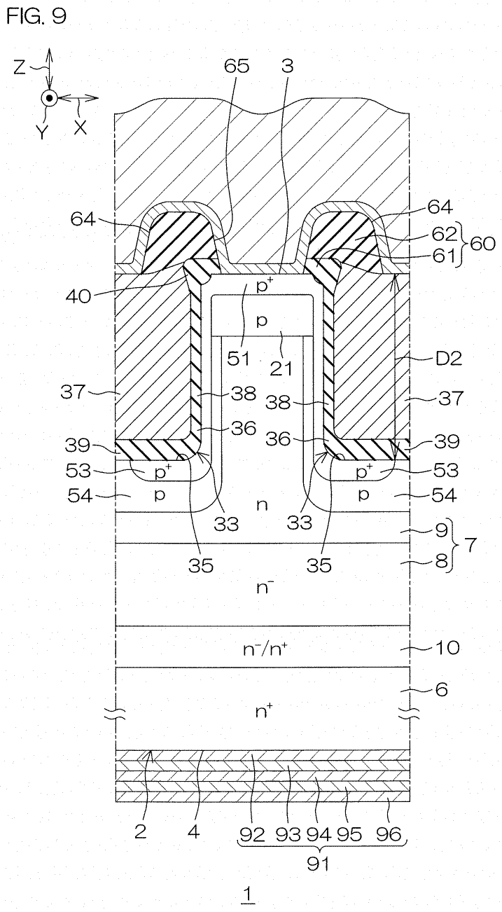

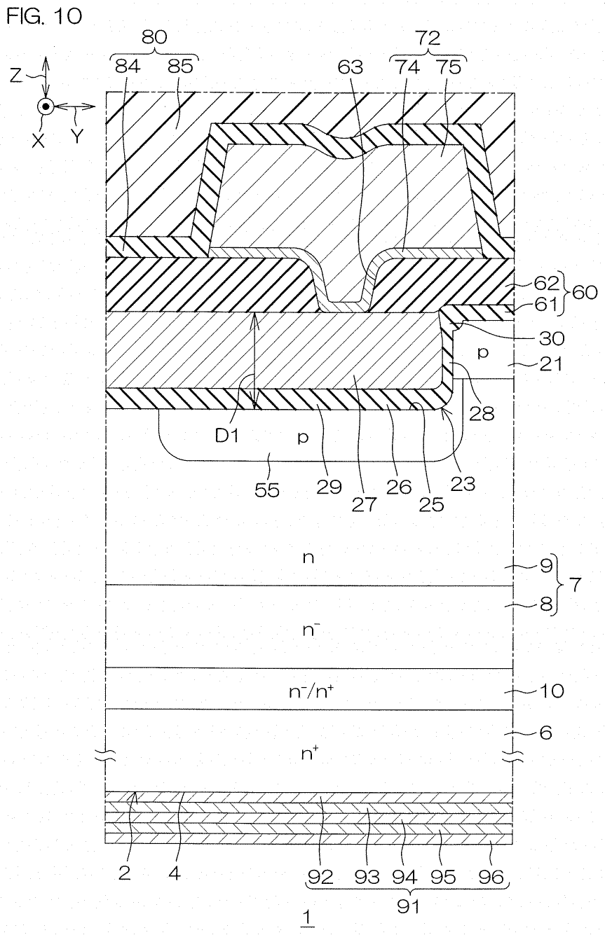

FIG. 1 is a plan view showing a SiC semiconductor device 1 according to a first preferred embodiment of the present invention. FIG. 2 is a plan view showing a layout of an electrode shown in FIG. 1. FIG. 3 is a plan view showing a layout of a first principal surface 3 of a SiC chip 2 shown in FIG. 1. FIG. 4 is a plan view in which a main portion of a structure shown in FIG. 3 is enlarged. FIG. 5 is a plan view in which another main portion of the structure shown in FIG. 3 is enlarged. FIG. 6 is a cross-sectional view along line VI-VI shown in FIG. 4. FIG. 7 is a cross-sectional view along line VII-VII shown in FIG. 4. FIG. 8 is a cross-sectional view along line VIII-VIII shown in FIG. 4. FIG. 9 is a cross-sectional view along line IX-IX shown in FIG. 4. FIG. 10 is a cross-sectional view along line X-X shown in FIG. 5.

Referring to FIG. 1 to FIG. 10, the SiC semiconductor device 1 is an electronic component that includes the SiC chip 2 constituted of an SiC monocrystal that is a hexagonal crystal in this embodiment. Additionally, in this embodiment, the SiC semiconductor device 1 is a semiconductor switching device that includes a SiC-MISFET (Metal Insulator Semiconductor Field Effect Transistor). The hexagonal SiC monocrystal has a plurality of kinds of polytypes that include a 2H (Hexagonal)-SiC monocrystal, a 4H-SiC monocrystal, a 6H-SiC monocrystal, etc. In this embodiment, an example is shown in which the SiC chip 2 is constituted of a 4H—SiC monocrystal, and yet other polytypes are not excluded.

The SiC chip 2 is formed in a rectangular parallelepiped shape. The SiC chip 2 has a first principal surface 3 on one side, a second principal surface 4 on the other side, and first to fourth side surfaces 5A to 5D that connect the first principal surface 3 and the second principal surface 4 together. The first principal surface 3 is a device surface on which a functional device is formed. The second principal surface 4 is a non-device surface on which a functional device is not formed. The first principal surface 3 and the second principal surface 4 are each formed in a quadrangular shape (specifically, rectangular shape) in a plan view seen from their normal directions Z (hereinafter, referred to simply as “in a plan view”).

The first principal surface 3 and the second principal surface 4 are arranged along a c plane of a SiC monocrystal. The c plane includes a silicon surface ((0001) plane) and a carbon surface ((000-1) plane) of the SiC monocrystal. Preferably, the first principal surface 3 is arranged along the silicon surface, and the second principal surface 4 is arranged along the carbon surface. The first principal surface 3 and the second principal surface 4 may have an off angle in which the surfaces are inclined at a predetermined angle in an off direction with respect to the c plane. Preferably, the off direction is an a axis direction ([11-20] direction) of the SiC monocrystal. The off angle may exceed 0° and may be equal to or less than 10°. Preferably, the off angle is equal to or less than 5°. Particularly preferably, the off angle is not less than 2° and not more than 4.5°.

The second principal surface 4 may be constituted of a rough surface having either one or both of grinding marks and annealing marks (specifically, laser irradiation marks). The annealing marks may include amorphized SiC and/or SiC silicided (alloyed) with a metal (specifically, Si). Preferably, the second principal surface 4 is constituted of an ohmic surface that has, at least, annealing marks.

The first side surface 5A and the second side surface 5B extend in a first direction X along the first principal surface 3, and face a second direction Y that intersects the first direction X (specifically, that perpendicularly intersects the first direction X). The first side surface 5A and the second side surface 5B form the short side of the SiC chip 2. The third side surface 5C and the fourth side surface 5D extend in the second direction Y, and face the first direction X. The first side surface 5A and the second side surface 5B form the long side of the SiC chip 2.

In this embodiment, the first direction X is an m axis direction ([1-100] direction) of the SiC monocrystal, and the second direction Y is an a axis direction of the SiC monocrystal. In other words, the first side surface 5A and the second side surface 5B are formed by an a plane of the SiC monocrystal, and the third side surface 5C and the fourth side surface 5D are formed by an m plane of the SiC monocrystal.

The first to fourth side surfaces 5A to 5D may be constituted of ground surfaces each of which has grinding marks formed by being cut by a dicing blade, or may be constituted of cleavage surfaces each of which has a modified layer formed by laser light irradiation. In detail, the modified layer is constituted of a region in which a part of the crystal structure of the SiC chip 2 has been modified into another property. In other words, the modified layer is constituted of a region in which density, refractive index, or mechanical strength (crystal strength) has been modified or other physical characteristics have been modified into a property differing from that of the SiC chip 2. The modified layer may include at least one layer among an amorphous layer, a melt rehardened layer, a defect layer, an dielectric breakdown layer, and a refractive-index change layer.

If the first to fourth side surfaces 5A to 5D are constituted of cleavage surfaces, the first side surface 5A and the second side surface 5B may form an inclined surface that has an inclination angle resulting from the off angle. When the normal direction Z is set at 0°, the inclination angle resulting from the off angle is an angle with respect to this normal direction Z. The first side surface 5A and the second side surface 5B may form an inclined surface extending along the c axis direction ([0001] direction) of the SiC monocrystal with respect to the normal direction Z.

The inclination angle resulting from the off angle is substantially equal to the off angle. The inclination angle resulting from the off angle may exceed 0° and may be equal to or less than 10° (preferably, not less than 2° and not more than 4.5°). The third side surface 5C and the fourth side surface 5D extend in the off direction (a axis direction), and therefore do not have an inclination angle resulting from the off angle. The third side surface 5C and the fourth side surface 5D planarly extend in the second direction Y (a axis direction) and in the normal direction Z. In detail, the third side surface 5C and the fourth side surface 5D are formed so as to be substantially perpendicular to the first principal surface 3 and to the second principal surface 4.

The SiC semiconductor device 1 includes an n type (first-conductivity-type) drain region 6 (first semiconductor region) formed at a surface layer portion of the second principal surface 4 of the SiC chip 2. The drain region 6 forms a drain of the MISFET. The drain region 6 is formed in the whole area of the surface layer portion of the second principal surface 4, and is exposed from the second principal surface 4 and from the first to fourth side surfaces 5A to 5D. In other words, the drain region 6 has the second principal surface 4 and parts of the first to fourth side surfaces 5A to 5D.

The drain region 6 has an n type impurity concentration that is substantially uniform in a thickness direction. The n type impurity concentration of the drain region 6 may be not less than 1×10¹⁸ cm³ and not more than 1×10²¹ cm⁻³. The thickness of the drain region 6 may be not less than 5 μm and not more than 300 μm. The thickness of the drain region 6 is, typically, not less than 50 μm and not more than 250 μm. The thickness of the drain region 6 is adjusted by grinding the second principal surface 4. In this embodiment, the drain region 6 is formed by an n type semiconductor substrate (SiC substrate).

The SiC semiconductor device 1 includes an n type drift region 7 (second semiconductor region) formed at a surface layer portion of the first principal surface 3 of the SiC chip 2. The drift region 7 is formed in the whole area of the surface layer portion of the first principal surface 3, and is exposed from the first principal surface 3 and from the first to fourth side surfaces 5A to 5D. In other words, the drift region 7 has the first principal surface 3 and parts of the first to fourth side surfaces 5A to 5D. The drift region 7 is electrically connected to the drain region 6, and forms the drain of the MISFET together with the drain region 6.

The drift region 7 has an n type impurity concentration less than the n type impurity concentration of the drain region 6. The n type impurity concentration of the drift region 7 may be not less than 1×10¹⁵ cm⁻³ and not more than 1×10¹⁸ cm⁻³. The thickness of the drift region 7 may be not less than 5 μm and not more than 20 μm. In this embodiment, the drift region 7 is formed by an n type epitaxial layer (SiC epitaxial layer).

Preferably, the drift region 7 has a concentration gradient in which its n type impurity concentration increases (specifically, increases gradually) from the second principal surface 4 (drain region 6) side toward the first principal surface 3. In other words, preferably, the drift region 7 has a low concentration region 8 positioned on the second principal surface 4 side and a high concentration region 9 that is positioned on the first principal surface 3 side and that is higher in concentration than the low concentration region 8. The high concentration region 9 is exposed from the first principal surface 3. The n type impurity concentration of the low concentration region 8 may be not less than 1.0×10¹⁵ cm⁻³ and not more than 1.0×10¹⁷ cm⁻³. The n type impurity concentration of the high concentration region 9 may be not less than 1.0×10¹⁶ cm⁻³ and not more than 1.0×10¹⁸ cm⁻³.

The SiC semiconductor device 1 includes an n type buffer region 10 (third semiconductor region) that is interposed between the drain region 6 and the drift region 7 in the SiC chip 2. The buffer region 10 has a concentration gradient in which its n type impurity concentration decreases (specifically, decreases gradually) from the n type impurity concentration of the drain region 6 toward the n type impurity concentration of the drift region 7. The buffer region 10 is interposed in the whole area between the drain region 6 and the drift region 7, and is exposed from the first to fourth side surfaces 5A to 5D. In other words, the buffer region 10 has parts of the first to fourth side surfaces 5A to 5D.

The buffer region 10 is electrically connected to the drain region 6 and to the drift region 7, and forms the drain of the MISFET together with the drain region 6 and with the drift region 7. The thickness of the buffer region 10 may be not less than 1 μm and not more than 10 μm. In this embodiment, the buffer region 10 is formed by an n type epitaxial layer (SiC epitaxial layer).

The SiC semiconductor device 1 includes an active region 11 set at the first principal surface 3. The active region 11 is a region in which the MISFET serving as a functional device is formed. In this embodiment, the number of active regions 11 set at the first principal surface 3 is only one. In other words, in this embodiment, the SiC semiconductor device 1 is constituted of a discrete device including a single active region 11.

The active region 11 is set at a central portion of the first principal surface 3 at a distance inwardly from the first to fourth side surfaces 5A to 5D. The active region 11 is set in a polygonal shape having four sides parallel to the first to fourth side surfaces 5A to 5D. In this embodiment, the active region 11 has a concave portion 11a that is hollowed toward an inward portion of the first principal surface 3 in a central portion of the side along the first side surface 5A in a plan view.

The SiC semiconductor device 1 includes an outer region 12 set at the first principal surface 3. The outer region 12 is a region in which a functional device is not formed, and is set outside the active region 11. The outer region 12 includes an annular region 12a and a pad region 12b. The annular region 12a extends in a belt shape along the first to fourth side surfaces 5A to 5D in a plan view, and is set in an annular shape (specifically, a quadrangular annular shape) that surrounds the active region 11. The pad region 12b convexly protrudes from a part, which is formed along the first side surface 5A, of the annular region 12a toward the active region 11 so as to be fitted to the concave portion 11a of the active region 11.

The SiC semiconductor device 1 includes a p type (second-conductivity-type) body region 21 formed at the surface layer portion of the first principal surface 3 in the active region 11. The body region 21 forms a part of a body diode of the MISFET. The p type impurity concentration of the body region 21 may be not less than 1.0×10¹⁶ cm⁻³ and not more than 1.0×10¹⁸ cm⁻³.

In detail, the body region 21 is formed at a surface layer portion of the drift region 7 in the whole area of the active region 11. In more detail, the body region 21 is formed at a surface layer portion of the high concentration region 9, and faces the drain region 6 (buffer region 10) with a part of the drift region 7 between the body region 21 and the drain region 6. The body region 21 may be also formed at the surface layer portion of the first principal surface 3 in the pad region 12b of the outer region 12.

The SiC semiconductor device 1 includes an n type source region 22 formed at a surface layer portion of the body region 21. The source region 22 forms a source of the MISFET. The source region 22 has an n type impurity concentration that exceeds the n type impurity concentration of the drift region 7 (high concentration region 9). The n type impurity concentration of the source region 22 may be not less than 1.0×10¹⁸ cm⁻³ and not more than 1.0×10²¹ cm⁻³.

The source region 22 is formed at a distance inwardly from a circumferential edge of the body region 21 in a plan view. The source region 22 is formed at a distance from the bottom portion of the body region 21 toward the first principal surface 3 side. The source region 22 forms a channel of the MISFET with the drift region 7 (high concentration region 9) in the body region 21.

The SiC semiconductor device 1 includes a trench insulated gate type MISFET formed at the first principal surface 3 in the active region 11. In detail, the SiC semiconductor device 1 includes a plurality of trench gate structures 23 formed at the first principal surface 3. The plurality of trench gate structures 23 form a gate of the MISFET. The plurality of trench gate structures 23 are each formed in a belt shape (rectangular shape) extending in the first direction X in a plan view, and are formed with intervals therebetween in the second direction Y.

Hence, the plurality of trench gate structures 23 are formed in a stripe shape extending in the first direction X in a plan view. The plurality of trench gate structures 23 partition a plurality of mesa portions 24 each of which has a plateau shape extending in the first direction X in the active region 11 in the first principal surface 3. In other words, the plurality of trench gate structures 23 are formed alternately with the plurality of mesa portions 24 in the second direction Y in such a manner as to allow the single mesa portion 24 to be sandwiched between the trench gate structures 23.

Preferably, the plurality of trench gate structures 23 extend in the first direction X so as to cross a line that passes through the central portion of the first principal surface 3 in the second direction Y in a plan view. Preferably, both end portions in the first direction X of the plurality of trench gate structures 23 are positioned between the circumferential edge of the body region 21 and a circumferential edge of the source region 22 in a plan view.

The plurality of trench gate structures 23 have first widths W1, respectively. The first width W1 is a width in a direction perpendicular to the direction (i.e., second direction Y) in which each of the trench gate structures 23 extends. The first width W1 may be not less than 0.1 μm and not more than 3 μm. Preferably, the first width W1 is not less than 0.5 μm and not more than 1.5 μm.

The plurality of trench gate structures 23 are formed with first intervals P1 between the trench gate structures 23 in the second direction Y. The first interval P1 is a distance between two of the trench gate structures 23 that are adjacent in the second direction Y. Preferably, the first interval P1 exceeds the first width W1 (W1<P1). The first interval P1 may be not less than 0.4 μm and not more than 5 μm. Preferably, the first interval P1 is not less than 0.8 μm and not more than 3 μm.

Each of the trench gate structures 23 has a first depth D1. The first depth D1 may be not less than 0.1 μm and not more than 3 μm. Preferably, the first depth D1 is not less than 0.5 μm and not more than 2 μm. Preferably, an aspect ratio D1/W1 of each of the trench gate structures 23 is not less than 1 and not more than 5. The aspect ratio D1/W1 is a ratio of the first depth D1 to the first width W1. Particularly preferably, the aspect ratio D1/W1 is 1.5 or more.

Each of the trench gate structures 23 includes a sidewall and a bottom wall. A part, which forms a long side, of the sidewall of each of the trench gate structures 23 is formed by the a plane of the SiC monocrystal. A part, which forms a short side, of the sidewall of each of the trench gate structures 23 is formed by the m plane of the SiC monocrystal. The bottom wall of each of the trench gate structures 23 is formed by the c plane of the SiC monocrystal.

Each of the trench gate structures 23 may be formed in a vertical shape having a substantially uniform opening width. Each of the trench gate structures 23 may be formed in a tapered shape having an opening width that becomes narrower toward the bottom wall. Preferably, the bottom wall of each of the trench gate structures 23 is formed in a curved shape toward the second principal surface 4. Of course, the bottom wall of each of the trench gate structures 23 may have a flat surface parallel to the first principal surface 3.

Each of the trench gate structures 23 is formed at the first principal surface 3 so as to cross the body region 21 and the source region 22 and so as to reach the drift region 7. In detail, each of the trench gate structures 23 is formed at a distance from the bottom portion of the drift region 7 toward the first principal surface 3 side, and faces the drain region 6 (buffer region 10) with a part of the drift region 7 between the trench gate structure 23 and the drain region 6. In this embodiment, each of the trench gate structures 23 is formed in the high concentration region 9, and faces the low concentration region 8 with a part of the high concentration region 9 between the trench gate structure 23 and the low concentration region 8. The sidewall of each of the trench gate structures 23 is in contact with the drift region 7, the body region 21, and the source region 22. The bottom wall of each of the trench gate structures 23 is in contact with the drift region 7.

The plurality of trench gate structures 23 include gate trenches 25, gate insulating films 26, and gate electrodes 27, respectively. One trench gate structure 23 is hereinafter described. The gate trench 25 forms the sidewall and the bottom wall of the trench gate structure 23. The sidewall and the bottom wall of the gate trench 25 are hereinafter referred to collectively as a “wall surface (inner wall and outer wall)” if necessary.

An opening edge portion of the gate trench 25 is inclined obliquely downward from the first principal surface 3 toward the gate trench 25. The opening edge portion is a connection portion between the first principal surface 3 and the sidewall of the gate trench 25. In this embodiment, the opening edge portion is formed in a curved shape that is hollowed toward the SiC chip 2. The opening edge portion may be formed in a curved shape toward the inward side of the gate trench 25.

The gate insulating film 26 is formed in a film shape on the inner wall of the gate trench 25, and defines a recessed space in the gate trench 25. The gate insulating film 26 covers the drift region 7, the body region 21, and the source region 22 in the inner wall of the gate trench 25. The gate insulating film 26 includes at least one among a silicon oxide film, a silicon nitride film, and a silicon oxynitride film. In this embodiment, the gate insulating film 26 has a single layer structure constituted of a silicon oxide film.

The gate insulating film 26 includes a first portion 28, a second portion 29, and a third portion 30. The first portion 28 covers the sidewall of the gate trench 25. The second portion 29 covers the bottom wall of the gate trench 25. The third portion 30 covers the opening edge portion. In this embodiment, the third portion 30 is bulged in a curved shape toward the inward side of the gate trench 25 in the opening edge portion.

The thickness of the first portion 28 may be not less than 10 nm and not more than 100 nm. The second portion 29 may have a thickness exceeding the thickness of the first portion 28. The thickness of the second portion 29 may be not less than 50 nm and not more than 200 nm. The third portion 30 has a thickness exceeding the thickness of the first portion 28. The thickness of the third portion 30 may be not less than 50 nm and not more than 200 nm. Of course, the gate insulating film 26 having a uniform thickness may be formed.

The gate electrode 27 is embedded in the gate trench 25 with the gate insulating film 26 between the gate electrode 27 and the gate trench 25. A gate potential is applied to the gate electrode 27. The gate electrode 27 controls the on/off of a channel formed in the body region 21. Preferably, the gate electrode 27 is constituted of conductive polysilicon. In this embodiment, the gate electrode 27 includes n type polysilicon that is doped with an n type impurity.

The gate electrode 27 faces the drift region 7, the body region 21, and the source region 22 with the gate insulating film 26 between these regions and the gate electrode 27. The gate electrode 27 has an electrode surface exposed from the gate trench 25. The electrode surface of the gate electrode 27 is formed in a curved shape that is hollowed toward the bottom wall of the gate trench 25, and is narrowed by the third portion 30 of the gate insulating film 26.

The SiC semiconductor device 1 includes a plurality of trench source structures 33 formed at the first principal surface 3 in the active region 11. The plurality of trench source structures 33 are each formed away from each of the trench gate structures 23 in a region (i.e., mesa portion 24) between two of the trench gate structures 23 that are adjacent in the first principal surface 3. Preferably, three or more trench source structures 33 are formed in each of the mesa portions 24.

In detail, the plurality of trench source structures 33 are each formed in a belt shape extending in the first direction X in each of the mesa portions 24, and are formed with intervals therebetween in the first direction X. In other words, the plurality of trench source structures 33 face each other in a direction that intersects (specifically, intersects perpendicularly) a direction in which two adjacent trench gate structures 23 face each other. In other words, while two adjacent trench gate structures 23 face each other in the second direction Y, two adjacent trench source structures 33 face each other in the first direction X.

The plurality of trench source structures 33 formed in each of the mesa portions 24 face the plurality of trench source structures 33 formed in a neighboring mesa portion 24 in a one-to-one correspondence relationship with the single trench gate structure 23 between the trench source structures 33 formed in each of the mesa portions 24 and the trench source structures 33 formed in the neighboring mesa portion 24. In other words, the plurality of trench source structures 33 are arranged in a matrix manner in the first and second directions X and Y with intervals between the trench source structures 33 as a whole in a plan view. Each of the trench source structures 33 is formed in a quadrangular shape in a plan view. In detail, each of the trench source structures 33 is formed in a rectangular shape (belt shape) extending in the first direction X in a plan view.

The plurality of trench source structures 33 have second widths W2, respectively. The second width W2 is a width in a direction (i.e., second direction Y) perpendicular to a direction in which each of the trench source structures 33 extends. The first width W1 may be not less than 0.1 μm and not more than 3 μm. Preferably, the first width W1 is not less than 0.5 μm and not more than 1.5 μm. The second width W2 may exceed the first width W1 (W1<W2), or may be equal to or less than the first width W1 (W1≥W2). In this embodiment, the second width W2 is substantially equal to the first width W1. Preferably, the second width W2 has a value within the range of ±10% of the value of the first width W1.

The plurality of trench source structures 33 have trench lengths L, respectively. The trench length L is a length in a direction (i.e., first direction X) in which each of the trench source structures 33 extends. The trench length L is arbitrary, and is adjusted in accordance with the length of each of the mesa portions 24 or in accordance with the number of trench source structures 33 formed in each of the mesa portions 24.

The trench length L may be equal to or more than the second width W2, and may be equal to or less than ten times as long as the second width W2 (W2≤L≤10×W2). Preferably, the trench length L is equal to or less than five times as long as the second width W2 (L≤5×W2). The trench length L may be equal to or more than the first interval P1 (P1≤L), or may be less than the first interval P1 (P1>L). In this embodiment, the trench length L exceeds the first interval P1, and is equal to or less than twice as long as the first interval P1 (P1<L≤2×P1).

Each of the trench source structures 33 has a second depth D2. Preferably, the second depth D2 is not less than 1.5 times and not more than 3 times as long as the first depth D1 of the trench gate structure 23. The second depth D2 may be not less than 0.5 μm and not more than 10 μm. Preferably, the second depth D2 is equal to or less than 5 μm. Preferably, an aspect ratio D2/W2 of each of the trench source structures 33 is not less than 1 and not more than 5. Particularly preferably, the aspect ratio D2/W2 is 2 or more. The aspect ratio D2/W2 is a ratio of the second depth D2 to the second width W2. Of course, the second depth D2 may be substantially equal to the first depth D1 of the trench gate structure 23.

The plurality of trench source structures 33 are formed with a second interval P2 therebetween in the first direction X in each of the mesa portions 24. The second interval P2 is a distance between two of the trench source structures 33 that are adjacent in the first direction X. The second interval P2 may be equal to or less than the first interval P1 (P2≤P1). Preferably, the second interval P2 is less than the first interval P1 (P2<P1). Particularly preferably, the second interval P2 is equal to or more than ¼ of the first interval P1 (¼×P1≤P2).

The second interval P2 may be equal to or more than the first width W1 of each of the trench gate structures 23 (W1≤P2), or may be less than the first width W1 (W1>P2). The second interval P2 may be equal to or more than the second width W2 of each of the trench source structures 33 (W2≤P2), or may be less than the second width W2 (W1>P2). The second interval P2 may be equal to or less than the trench length L (P2≤L). Preferably, the second interval P2 is less than the trench length L (P2<L). The second interval P2 may be not less than 0.4 μm and not more than 5 μm. Preferably, the second interval P2 is not less than 0.8 μm and not more than 3 μm.

The plurality of trench source structures 33 are formed with a third interval P3 therebetween in the second direction Y. The third interval P3 is a distance between two of the trench source structures 33 that are adjacent in the second direction Y. The third interval P3 may be not less than 0.4 μm and not more than 5 μm. Preferably, the third interval P3 is not less than 0.8 μm and not more than 3 μm. The third interval P3 may exceed the first interval P1 (P1<P3), or may be equal to or less than the first interval P1 (P1≥P3).

The plurality of trench source structures 33 partition a plurality of segment portions 34 each of which is constituted of a part of each of the mesa portions 24 in each of the mesa portions 24. In this embodiment, the plurality of segment portions 34 include a plurality of first segment portions 34A and a plurality of second segment portions 34B that are arranged alternately along the first direction X in each of the mesa portions 24. The plurality of first segment portions 34A are each a region in which a semiconductor region is to be formed, and the plurality of second segment portions 34B are each a region in which a semiconductor region differing from that of the plurality of first segment portions 34A is to be formed.

The plurality of first segment portions 34A partitioned in each of the mesa portions 24 face the plurality of first segment portions 34A partitioned in a neighboring mesa portion 24 with the single trench gate structure 23 therebetween in the second direction Y in a one-to-one correspondence relationship. The plurality of second segment portions 34B partitioned in each of the mesa portions 24 face the plurality of second segment portions 34B partitioned in a neighboring mesa portion 24 with the single trench gate structure 23 therebetween in the second direction Y in a one-to-one correspondence relationship.

Each of the trench source structures 33 includes a sidewall and a bottom wall. A part, which extends in the first direction X (part forming a long side), of the sidewall of each of the trench source structures 33 is formed by the a plane of the SiC monocrystal. A part, which extends in the second direction Y (part forming a short side), of the sidewall of each of the trench source structures 33 is formed by the m plane of the SiC monocrystal. The bottom wall of each of the trench source structures 33 is formed by the c plane of the SiC monocrystal.

Each of the trench source structures 33 may be formed in a vertical shape having a substantially uniform opening width. Each of the trench source structures 33 may be formed in a tapered shape having an opening width that becomes narrower toward the bottom wall. Preferably, the bottom wall of each of the trench source structures 33 is formed in a curved shape toward the second principal surface 4. Of course, the bottom wall of each of the trench source structures 33 may have a flat surface parallel to the first principal surface 3.

Each of the trench source structures 33 is formed at the first principal surface 3 so as to cross the body region 21 and the source region 22 and so as to reach the drift region 7. In detail, each of the trench source structures 33 is formed at a distance from the bottom portion of the drift region 7 toward the first principal surface 3 side, and faces the drain region 6 (buffer region 10) with a part of the drift region 7 between the trench source structure 33 and the drain region 6. In this embodiment, each of the trench source structures 33 is formed in the high concentration region 9, and faces the low concentration region 8 with a part of the high concentration region 9 between the trench source structure 33 and the low concentration region 8.

The sidewall of each of the trench source structures 33 is in contact with the drift region 7, the body region 21, and the source region 22. The bottom wall of each of the trench source structures 33 is in contact with the drift region 7. In this embodiment, each of the trench source structures 33 is formed more deeply than each of the trench gate structures 23. In other words, the bottom wall of each of the trench source structures 33 is positioned on the bottom portion side of the drift region 7 (high concentration region 9) with respect to the bottom wall of each of the trench gate structures 23.

The plurality of trench source structures 33 include source trenches 35, source insulating films 36, and source electrodes 37, respectively. One trench source structure 33 will be hereinafter described. The source trench 35 forms the sidewall and the bottom wall of the trench source structure 33. The sidewall and the bottom wall of the source trench 35 are hereinafter referred to collectively as a “wall surface (inner wall and outer wall)” if necessary.

An opening edge portion of the source trench 35 is inclined obliquely downward from the first principal surface 3 toward the source trench 35. The opening edge portion is a connection portion between the first principal surface 3 and the sidewall of the source trench 35. In this embodiment, the opening edge portion is formed in a curved shape hollowed toward the SiC chip 2. The opening edge portion may be formed in a curved shape toward the inward side of the source trench 35.

The source insulating film 36 is formed in a film shape on the inner wall of the source trench 35, and defines a recessed space in the source trench 35. The source insulating film 36 covers the drift region 7, the body region 21, and the source region 22 in the inner wall of the source trench 35. The source insulating film 36 includes at least one among a silicon oxide film, a silicon nitride film, and a silicon oxynitride film. In this embodiment, the source insulating film 36 has a single layer structure constituted of a silicon oxide film.

The source insulating film 36 includes a first portion 38, a second portion 39, and a third portion 40. The first portion 38 covers the sidewall of the source trench 35. The second portion 39 covers the bottom wall of the source trench 35. The third portion 40 covers the opening edge portion. In this embodiment, the third portion 40 is bulged in a curved shape toward the inward side of the source trench 35 in the opening edge portion.

The thickness of the first portion 38 may be not less than 10 nm and not more than 100 nm. The second portion 39 may have a thickness exceeding the thickness of the first portion 38. The thickness of the second portion 39 may be not less than 50 nm and not more than 200 nm. The third portion 40 has a thickness exceeding the thickness of the first portion 38. The thickness of the third portion 40 may be not less than 50 nm and not more than 200 nm. Of course, the source insulating film 36 having a uniform thickness may be formed.

The source electrode 37 is embedded in the source trench 35 with the source insulating film 36 between the source electrode 37 and the source trench 35. A source potential (for example, reference potential) is applied to the source electrode 37. Preferably, the source electrode 37 is constituted of the same material as the gate electrode 27. In other words, preferably, the source electrode 37 is constituted of conductive polysilicon. In this embodiment, the source electrode 37 includes n type polysilicon that is doped with an n type impurity.

The source electrode 37 faces the drift region 7, the body region 21, and the source region 22 with the source insulating film 36 between these regions and the source electrode 37. A source potential is applied to the source electrode 37. The source electrode 37 has an electrode surface exposed from the source trench 35. The electrode surface of the source electrode 37 is formed in a curved shape hollowed toward the bottom wall of the source trench 35, and is narrowed by the third portion 30 of the source insulating film 36.

The SiC semiconductor device 1 includes a plurality of p type body connection regions 51 formed in a region partitioned by two of the trench source structures 33 that are adjacent in the surface layer portion of the body region 21. Each of the body connection regions 51 has a p type impurity concentration exceeding the p type impurity concentration of the body region 21. The p type impurity concentration of each of the body connection regions 51 may be not less than 1.0×10¹⁸ cm⁻³ and not more than 1.0×10²¹ cm⁻³.

The plurality of body connection regions 51 are each electrically connected to the body region 21. In detail, the plurality of body connection regions 51 are each formed at the surface layer portion of the body region 21 in the plurality of first segment portions 34A. Each of the body connection regions 51 is formed in such a manner as to offset the n type impurity of the source region 22 by means of the p type impurity in each of the first segment portions 34A, and is electrically connected to the body region 21.

Preferably, each of the body connection regions 51 is in contact with at least one of two of the trench source structures 33 that are adjacent in the first direction X. In this embodiment, each of the body connection regions 51 is in contact with the sidewall of two of the trench source structures 33 that are adjacent in the first direction X. In other words, each of the body connection regions 51 faces the source electrode 37 with the source insulating film 36 of the trench source structure 33 on one side between the body connection region 51 and the source electrode 37, and faces the source electrode 37 with the source insulating film 36 of the trench source structure 33 on the other side between the body connection region 51 and the source electrode 37 in each of the first segment portions 34A. Each of the body connection regions 51 is formed at a distance from the bottom wall of two of the trench source structures 33 that are adjacent in the first direction X toward the first principal surface 3 side. In detail, each of the body connection regions 51 is formed at a distance from an intermediate portion in the depth direction of each of the trench source structures 33 toward the first principal surface 3 side.

Each of the body connection regions 51 is formed more widely than the trench source structure 33 in a plan view, and projects toward either one or both of the trench gate structures 23 positioned on both sides. In this embodiment, each of the body connection regions 51 is formed in the whole area of each of the first segment portions 34A in a plan view, and projects toward the trench gate structure 23 on one side and toward the trench gate structure 23 on the other side.

Each of the body connection regions 51 is formed at a distance inwardly from two of the trench gate structures 23 that are adjacent in the second direction Y so as to expose a part of the source region 22 from the first principal surface 3 in a plan view. In this embodiment, each of the body connection regions 51 is formed at a distance from adjoining plurality of second segment portions 34B toward the first segment portion 34A side. Therefore, each of the body connection regions 51 exposes the whole area of the plurality of second segment portions 34B.

Each of the body connection regions 51 has a third width W3 in the second direction Y. The third width W3 is less than the first interval P1 between the plurality of trench gate structures 23 (W3<P1). Preferably, the third width W3 is equal to or more than the second width W2 of each of the trench source structures 33 (W2≤W3). Of course, the third width W3 may be less than the second width W2 (W2>W3).

The SiC semiconductor device 1 includes a plurality of n type source connection regions 52 formed in a region defined by two of the trench source structures 33 that are adjacent in a region differing from the body connection region 51 in the surface layer portion of the body region 21. Each of the source connection regions 52 has an n type impurity concentration exceeding the n type impurity concentration of the drift region 7 (high concentration region 9). The n type impurity concentration of each of the source connection regions 52 may be not less than 1.0×10¹⁸ cm⁻³ and not more than 1.0×10²¹ cm⁻³.

The plurality of source connection regions 52 are each electrically connected to the source region 22. In detail, the plurality of source connection regions 52 are formed in the second segment portion 34B. In other words, the plurality of source connection regions 52 are formed in the segment portion 34 differing from the plurality of body connection regions 51. Additionally, the plurality of source connection regions 52 are formed alternately with the plurality of body connection regions 51 with the plurality of trench source structures 33 therebetween in each of the mesa portions 24.

In this embodiment, each of the source connection regions 52 is formed in the whole area of each of the second segment portions 34B in a plan view. Each of the source connection regions 52 faces the source electrode 37 with the source insulating film 36 of the trench source structure 33 on one side between the source connection region 52 and the source electrode 37 in each of the second segment portions 34B, and faces the source electrode 37 with the source insulating film 36 of the trench source structure 33 on the other side between the source connection region 52 and the source electrode 37 in each of the second segment portions 34B. Additionally, each of the source connection regions 52 faces each of the body connection regions 51 in the first direction X with the trench source structure 33 between the source connection region 52 and the body connection region 51.

In this embodiment, each of the source connection regions 52 is formed by using a part of the source region 22. Therefore, each of the source connection regions 52 has an n type impurity concentration substantially equal to the n type impurity concentration of the source region 22. Of course, each of the source connection regions 52 may have an n type impurity concentration exceeding the n type impurity concentration of the source region 22. Each of the source connection regions 52 partially includes a p type impurity that has been offset by an n type impurity, and may have an n type impurity concentration exceeding the n type impurity concentration of the drift region 7 (high concentration region 9) as a whole. In this case, the n type impurity concentration of each of the source connection regions 52 may be less than the n type impurity concentration of the source region 22.

As thus described, in a cross section that crosses each of the mesa portions 24 in the first direction X, the plurality of trench source structures 33, the plurality of body connection regions 51, and the plurality of source connection regions 52 are formed so as to be arranged in a line in the first direction X. Additionally, in a cross section that crosses the first segment portion 34A in the second direction Y, the plurality of trench gate structures 23, the plurality of body connection regions 51, and the plurality of source regions 22 are formed so as to be arranged in a line in the second direction Y.

Additionally, in the cross section that crosses the second segment portion 34B in the second direction Y, the plurality of trench gate structures 23, the plurality of source connection regions 52, and the plurality of source regions 22 are formed so as to be arranged in a line in the second direction Y. In other words, the SiC semiconductor device 1 does not have the body connection region 51 and the source connection region 52 that are adjacent to each other in a direction (i.e., second direction Y) intersecting each of the trench source structures 33 in each of the mesa portions 24.

In other words, the plurality of source connection regions 52 are disposed so as to be separated from the plurality of body connection regions 51 by means of the plurality of trench source structures 33, respectively, and do not have its parts connected directly to the plurality of body connection regions 51. The plurality of source connection regions 52 are electrically connected to the plurality of body connection regions 51 through the source region 22.

The SiC semiconductor device 1 includes a plurality of p type trench connection regions 53 formed in a region along the wall surface of the plurality of trench source structures 33 in the drift region 7. Each of the trench connection regions 53 has a p type impurity concentration exceeding the p type impurity concentration of the body region 21. The p type impurity concentration of each of the trench connection regions 53 may be not less than 1.0×10¹⁸ cm⁻³ and not more than 1.0×10²¹ cm⁻³.

The plurality of trench connection regions 53 are electrically connected to the plurality of body connection regions 51, respectively. In detail, each of the trench connection regions 53 are constituted of a region led out from each of the body connection regions 51 to the wall surface of an adjacent trench source structure 33. In this embodiment, two trench connection regions 53 are led out from each of the body connection regions 51 toward the wall surface of the trench source structure 33 on one side and toward the wall surface of the trench source structure 33 on the other side. In other words, each of the trench connection regions 53 has a p type impurity concentration substantially equal to the p type impurity concentration of each of the body connection regions 51. Additionally, the plurality of trench connection regions 53 are formed in a one-to-one correspondence relationship with respect to the plurality of trench source structures 33, respectively, in a plan view.

In this embodiment, each of the trench connection regions 53 extends in the first direction X so as to cross the intermediate portion of the trench source structure 33 in a plan view. Each of the trench connection regions 53 partially covers the wall surface of the trench source structure 33 so as to expose a part of the wall surface of the trench source structure 33. In detail, each of the trench connection regions 53 is formed at a distance from each of the second segment portions 34B toward each first segment portion 34A side.

Therefore, each of the trench connection regions 53 exposes an end portion (sidewall and bottom wall) on the second segment portion 34B side of the trench source structure 33. Additionally, each of the trench connection regions 53 exposes the source connection region 52 (second segment portion 34B). Each of the trench connection regions 53 is formed at a distance inwardly from two of the trench gate structures 23 that are adjacent so as to expose a part of the source region 22 from the first principal surface 3 with respect to the second direction Y.

Each of the trench connection regions 53 covers the sidewall and the bottom wall of each of the trench source structures 33 in the drift region 7. Each of the trench connection regions 53 is connected to the body connection region 51 in a part, which partitions the first segment portion 34A, of the sidewall of each of the trench source structures 33.

The bottom portion of each of the trench connection regions 53 is formed at a distance from the bottom portion of the drift region 7 toward the first principal surface 3 side, and faces the drain region 6 (buffer region 10) with a part of the drift region 7 between the drain region 6 and the bottom portion of the trench connection region 53. In this embodiment, each of the trench connection regions 53 is formed in the high concentration region 9, and faces the low concentration region 8 with a part of the high concentration region 9 between the trench connection region 53 and the low concentration region 8. Each of the trench connection regions 53 faces the source electrode 37 with the source insulating film 36 between the trench connection region 53 and the source electrode 37.

The SiC semiconductor device 1 includes a plurality of p type well regions 54 each of which is formed in a region along the wall surface of the plurality of trench source structures 33 in the drift region 7. Each of the well regions 54 has a p type impurity concentration less than the p type impurity concentration of each of the trench connection regions 53. The p type impurity concentration of each of the well regions 54 may be not less than 1.0×10¹⁶ cm⁻³ and not more than 1.0×10¹⁸ cm⁻³.

The plurality of well regions 54 are formed in a one-to-one correspondence relationship with respect to the plurality of trench source structures 33, respectively. Each of the well regions 54 is formed in a belt shape extending along each of the trench source structures 33 in a plan view. Each of the well regions 54 is formed at a distance from the trench gate structure 23 toward the trench source structure 33 side, and exposes the trench gate structure 23.

Each of the well regions 54 covers the sidewall and the bottom wall of each of the trench source structures 33. Each of the well regions 54 is formed at a distance from the bottom portion of the drift region 7 (high concentration region 9) toward the first principal surface 3 side, and faces the drain region 6 (buffer region 10) with a part of the drift region 7 between the well region 54 and the drain region 6. In this embodiment, each of the well regions 54 is formed in the high concentration region 9, and faces the low concentration region 8 with a part of the high concentration region 9 between the well region 54 and the low concentration region 8.

Each of the well regions 54 covers the sidewall of each of the trench source structures 33 over the whole circumference of each of the trench source structures 33. In other words, each of the well regions 54 includes its part positioned at the first segment portion 34A and its part positioned at the second segment portion 34B. Each of the well regions 54 covers each of the trench source structures 33 with the trench connection region 53 therebetween. In other words, each of the well regions 54 includes a part, which directly covers each of the trench source structures 33, of the well region 54 and a part, which covers each of the trench source structures 33, of the well region 54 with the trench connection region 53 therebetween. Each of the well regions 54 is connected to the body region 21 in the part, which covers the sidewall of each of the trench source structures 33, of the well region 54.

Preferably, the thickness of the part, which covers the bottom wall of each of the trench source structures 33, of each of the well regions 54 exceeds the thickness of the part, which covers the sidewall of each of the trench source structures 33, of each of the well regions 54. The thickness of the part, which covers the sidewall of the trench source structure 33, of each of the well regions 54 is the thickness in the normal direction of the sidewall of the trench source structure 33. The thickness of the part, which covers the bottom wall of the trench source structure 33, of each of the well regions 54 is the thickness in the normal direction of the bottom wall of the trench source structure 33.

The part, which covers the bottom wall of the plurality of trench source structure 33, of each of the plurality of well regions 54 is formed with a substantially uniform depth. The plurality of well regions 54 form a pn junction portion with the drift region 7 (high concentration region 9), and expand a depletion layer toward the trench gate structure 23 (gate trench 25). The plurality of well regions 54 bring the trench insulated gate type MISFET close to the structure of the pn junction diode, and ease an electric field in the SiC chip 2.

Preferably, the plurality of well regions 54 are formed such that the depletion layer overlaps the bottom wall of an adjacent trench gate structure 23. Additionally, preferably, the plurality of well regions 54 are formed such that the depletion layer overlaps the bottom wall of an adjacent trench source structure 33. The high concentration region 9 interposed between the plurality of well regions 54 reduces JFET (Junction Field Effect Transistor) resistance. The high concentration region 9 positioned directly under the plurality of well regions 54 reduces current spreading resistance. The low concentration region 8 raises the withstand voltage of the SiC chip 2 in the thus formed structure.

The SiC semiconductor device 1 includes a plurality of p type gate well regions 55 formed in regions along the wall surfaces of both end portions of the plurality of trench gate structures 23, respectively, in the drift region 7 with respect to the first direction X. Each of the gate well regions 55 has a p type impurity concentration less than the p type impurity concentration of each of the trench connection regions 53. The p type impurity concentration of each of the gate well regions 55 may be not less than 1.0×10¹⁶ cm⁻³ and not more than 1.0×10¹⁸ cm⁻³. Preferably, the p type impurity concentration of each of the gate well regions 55 is substantially equal to the p type impurity concentration of each of the well regions 54.

The plurality of gate well regions 55 are each formed at least in a region between a peripheral edge portion of the body region 21 and a peripheral edge portion of the source region 22. Each of the gate well regions 55 is formed in a belt shape extending along each of the trench gate structures 23 in a plan view. Each of the gate well regions 55 is formed at a distance from the trench source structure 33 toward the trench gate structure 23 side, and exposes a part, which is along the source region 22, of the trench gate structure 23.

Each of the gate well regions 55 covers the sidewall and the bottom wall of each of the trench gate structures 23. Each of the gate well regions 55 is formed at a distance from the bottom portion of the drift region 7 (high concentration region 9) toward the first principal surface 3 side, and faces the drain region 6 (buffer region 10) with a part of the drift region 7 between the gate well region 55 and the drain region 6. In this embodiment, each of the gate well regions 55 is formed in the high concentration region 9, and faces the low concentration region 8 with a part of the high concentration region 9 between the gate well region 55 and the low concentration region 8. Each of the gate well regions 55 is connected to the body region 21 in a part, which covers the sidewall of each of the trench gate structures 23, of each of the gate well regions 55.

The bottom portion of the plurality of gate well regions 55 is positioned on the bottom wall side of the trench gate structure 23 with respect to the bottom portion of the plurality of well regions 54. Preferably, the thickness of the part, which covers the bottom wall of each of the trench gate structures 23, of each of the gate well regions 55 exceeds the thickness of the part, which covers the sidewall of each of the trench gate structures 23, of each of the gate well regions 55. The thickness of the part, which covers the sidewall of the trench gate structure 23, of each of the gate well regions 55 is the thickness in the normal direction of the sidewall of the trench gate structure 23. The thickness of the part, which covers the bottom wall of the trench gate structure 23, of each of the gate well regions 55 is the thickness in the normal direction of the bottom wall of the trench gate structure 23.

The part, which covers the bottom wall of the plurality of trench gate structures 23, of the bottom portion of the plurality of gate well regions 55 is formed with a substantially uniform depth. The plurality of gate well region 55 forms a pn junction portion with the drift region 7 (high concentration region 9), and expands a depletion layer toward the trench gate structure 23 and toward the trench source structure 33. The plurality of gate well regions 55 bring the trench insulated gate type MISFET close to the structure of the pn junction diode, and ease an electric field in the SiC chip 2.

The SiC semiconductor device 1 includes an interlayer insulating film 60 that covers the first principal surface 3. In this embodiment, the interlayer insulating film 60 has a laminated structure that includes a first insulating film 61 and a second insulating film 62 that are laminated together in this order from the first principal surface 3 side.

The first insulating film 61 is formed in a film shape along the first principal surface 3, and is continuous to the plurality of gate insulating films 26 and to the plurality of source insulating films 36. The first insulating film 61 exposes the plurality of gate electrodes 27 and the plurality of source electrodes 37. The first insulating film 61 includes at least one among a silicon oxide film, a silicon nitride film, and a silicon oxynitride film. In this embodiment, the first insulating film 61 includes an NSG (Nondoped Silicate Glass) film that is an example of the silicon oxide film. The thickness of the first insulating film 61 may be not less than 10 nm and not more than 300 nm.

The second insulating film 62 is formed in a film shape along the first insulating film 61, and selectively covers the plurality of trench gate structures 23 and the plurality of trench source structures 33. The second insulating film 62 includes at least one among a silicon oxide film, a silicon nitride film, and a silicon oxynitride film. In this embodiment, the second insulating film 62 includes a PSG (Phosphor Silicate Glass) film that is an example of the silicon oxide film. The thickness of the second insulating film 62 may be not less than 50 nm and not more than 500 nm. Preferably, the thickness of the second insulating film 62 exceeds the thickness of the first insulating film 61.

The interlayer insulating film 60 includes a plurality of gate openings 63, a plurality of first source openings 64, a plurality of second source openings 65, and a plurality of third source openings 66. The gate opening 63 is an opening for the trench gate structure 23. The first source opening 64 is an opening for the trench source structure 33. The second source opening 65 is an opening for the body connection region 51. The third source opening 66 is an opening for the source connection region 52.

The plurality of gate openings 63 are formed on the both end portion sides of the plurality of trench gate structures 23, respectively, and expose the plurality of trench gate structures 23 (specifically, gate electrodes 27), respectively, in a one-to-one correspondence relationship. The planar shape of each of the gate openings 63 is arbitrary, and each of the gate openings 63 may be formed in a square shape, a rectangular shape, a circular shape, etc.

The plurality of first source openings 64 expose the plurality of trench source structures 33 (specifically, source electrodes 37), respectively, in a one-to-one correspondence relationship. Each of the first source openings 64 is formed in a region surrounded by the sidewall of each of the trench source structures 33 in a plan view. In detail, each of the first source openings 64 is formed at a distance inwardly from the sidewall of each of the trench source structures 33, and exposes only the source electrode 37. The planar shape of each of the first source openings 64 is arbitrary, and each of the first source openings 64 may be formed in a square shape, a rectangular shape, a circular shape, etc.

The plurality of second source openings 65 expose the plurality of body connection regions 51, respectively, in a one-to-one correspondence relationship. With respect to each of the mesa portions 24, the plurality of second source openings 65 are formed at a distance from the plurality of first source openings 64 in the first direction X, and face the plurality of first source openings 64, respectively, in the first direction X. The planar shape of each of the second source openings 65 is arbitrary, and each of the second source openings 65 may be formed in a square shape, a rectangular shape, a circular shape, etc.

The plurality of third source openings 66 expose the plurality of source connection regions 52, respectively, in a one-to-one correspondence relationship. With respect to each of the mesa portions 24, the plurality of third source openings 66 are formed at a distance from the plurality of first source openings 64 and from the plurality of second source openings 65 in the first direction X, and face the plurality of first source openings 64 and the plurality of second source openings 65, respectively, in the first direction X.

The planar shape of each of the third source openings 66 is arbitrary, and each of the third source openings 66 may be formed in a square shape, a rectangular shape, a circular shape, etc. With respect to each of the mesa portions 24, the plurality of first source openings 64, the plurality of second source openings 65, and the plurality of third source openings 66 are arranged with intervals therebetween on a line connecting the plurality of trench source structures 33 together in the first direction X in a plan view.

The SiC semiconductor device 1 includes a gate principal surface electrode 71 disposed on the interlayer insulating film 60. The gate principal surface electrode 71 is an external terminal that is externally connected to a lead wire (for example, bonding wire), and a gate potential is applied to the gate principal surface electrode 71. The gate principal surface electrode 71 is electrically connected to the plurality of trench gate structures 23 (gate electrodes 27), and transmits the input gate potential (gate signal) to the plurality of trench gate structures 23 (gate electrodes 27).

The gate potential may be not less than 10 V and not more than 50 V (for example, about 30 V). The gate principal surface electrode 71 is disposed on the pad region 12b. The gate principal surface electrode 71 faces the pad region 12b with the interlayer insulating film 60 between the gate principal surface electrode 71 and the pad region 12b. In this embodiment, the gate principal surface electrode 71 is formed in a quadrangular shape having four sides parallel to the first principal surface 3 in a plan view.

The SiC semiconductor device 1 includes a gate wiring electrode 72 led out from the gate principal surface electrode 71 onto the interlayer insulating film 60. The gate wiring electrode 72 transmits a gate potential applied onto the gate principal surface electrode 71 to other regions. The gate wiring electrode 72 extends in a belt shape so as to partition the active region 11 from a plurality of directions in a plan view. In this embodiment, the gate wiring electrode 72 extends in a belt shape along the first side surface 5A, the third side surface 5C, and the fourth side surface 5D so as to partition the active region 11 from three directions in a plan view.

The gate wiring electrode 72 intersects (in detail, perpendicularly intersects) both end portions of the plurality of trench gate structures 23 in a plan view. The gate wiring electrode 72 enters the plurality of gate openings 63 from above the interlayer insulating film 60, and is electrically connected to the plurality of gate electrodes 27. Hence, the gate potential applied onto the gate principal surface electrode 71 is transmitted to the trench gate structures 23 through the plurality of gate wiring electrode 72.

The SiC semiconductor device 1 includes a source principal surface electrode 73 disposed on the interlayer insulating film 60 away from the gate principal surface electrode 71 and from the gate wiring electrode 72. The source principal surface electrode 73 is an external terminal that is externally connected to a lead wire (for example, bonding wire), and a source potential is applied onto the source principal surface electrode 73.

The source principal surface electrode 73 is electrically connected to the plurality of trench source structures 33 (source electrodes 37), to the plurality of body connection regions 51, and to the plurality of source connection regions 52, and transmits the input source potential to the plurality of trench source structures 33 (source electrodes 37), to the plurality of body connection regions 51, and to the plurality of source connection regions 52. The source potential may be a reference potential (for example, ground potential).

In detail, the source principal surface electrode 73 is disposed in a region partitioned by the gate principal surface electrode 71 and by the gate wiring electrode 72 in the interlayer insulating film 60, and faces the active region 11. In this embodiment, the source principal surface electrode 73 has a concave portion 73a that is hollowed from a central portion of a side along the first side surface 5A toward an inward portion thereof so as to match the gate principal surface electrode 71 in a plan view. The source principal surface electrode 73 faces all of the plurality of trench gate structures 23 and all of the plurality of trench source structures 33.

The source principal surface electrode 73 enters the plurality of first source openings 64, the plurality of second source openings 65, and the plurality of third source openings 66 from above the interlayer insulating film 60, and is electrically connected to the plurality of source electrodes 37, to the plurality of body connection regions 51, and to the plurality of source connection regions 52. Hence, the source potential applied onto the source principal surface electrode 73 is transmitted to the plurality of source electrodes 37, to the plurality of body connection regions 51, and to the plurality of source connection regions 52.

The source potential is transmitted to the body region 21, to the source region 22, to the plurality of trench connection regions 53, to the plurality of well regions 54, and to the plurality of gate well regions 55 through the plurality of body connection regions 51 and the plurality of source connection regions 52. With respect to each of the mesa portions 24, the source principal surface electrode 73 is electrically connected to the plurality of trench source structures 33, to the plurality of body connection regions 51, and to the plurality of source connection regions 52 on a line connecting the plurality of trench source structures 33 together in the first direction X.

The gate principal surface electrode 71, the gate wiring electrode 72, and the source principal surface electrode 73 each have a laminated structure including a first electrode film 74 and a second electrode film 75 that are laminated together in this order from the interlayer-insulating film 60 side.

The first electrode film 74 is formed in a film shape along the interlayer insulating film 60. In this embodiment, the first electrode film 74 is constituted of a Ti-based metal film. The first electrode film 74 includes at least one of a titanium film and a titanium nitride film. The first electrode film 74 may have a single layer structure constituted of a titanium film or a titanium nitride film. In this embodiment, the first electrode film 74 has a laminated structure including a titanium film and a titanium nitride film that are laminated together in this order from the first principal surface 3 side.

The second electrode film 75 is formed in a film shape along a principal surface of the first electrode film 74. The first electrode film 74 is constituted of a Cu-based metal film or an Al-based metal film. The first electrode film 74 may include at least one among a pure Cu film (Cu film whose purity is 99% or more), a pure Al film (Al film whose purity is 99% or more), an Al—Cu alloy film, an Al—Si alloy film, and an Al—Si—Cu alloy film. In this embodiment, the first electrode film 74 has a single layer structure constituted of an Al—Cu alloy film.

The SiC semiconductor device 1 includes an uppermost insulating film 80 that selectively covers the gate principal surface electrode 71, the gate wiring electrode 72, and the source principal surface electrode 73 on the interlayer insulating film 60. The uppermost insulating film 80 has a first pad opening 81 that covers the whole area of the gate wiring electrode 72 and that exposes the gate principal surface electrode 71 and a second pad opening 82 that exposes the source principal surface electrode 73.

The planar shape of the first pad opening 81 and the planar shape of the second pad opening 82 are arbitrary. The uppermost insulating film 80 is formed at a distance inwardly from the first to fourth side surfaces 5A to 5D, and partitions a dicing street 83 that exposes the interlayer insulating film 60 with the first to fourth side surfaces 5A to 5D. The width of the dicing street 83 may be not less than 1 μm and not more than 50 μm. The width of the dicing street 83 is a width in a direction perpendicular to a direction in which the dicing street 83 extends.

In this embodiment, the uppermost insulating film 80 has a laminated structure including an inorganic insulating film 84 and an organic insulating film 85 that are laminated together in this order from the interlayer-insulating film 60 side. The inorganic insulating film 84 is constituted of an inorganic insulator having a comparatively high denseness, and has a barrier property (shielding ability) against water (moisture). The inorganic insulating film 84 shields water (moisture) from the outside, and protects the SiC chip 2, the gate principal surface electrode 71, the gate wiring electrode 72, the source principal surface electrode 73, and the like from undesirable oxidation. The inorganic insulating film 84 may be referred to as a passivation film.

The inorganic insulating film 84 may have a laminated structure including a plurality of insulating films, or may have a single layer structure constituted of a single insulating film. Preferably, the inorganic insulating film 84 includes at least one among a silicon oxide film, a silicon nitride film, and a silicon oxynitride film. The inorganic insulating film 84 may have a laminated structure including a plurality of silicon oxide films, a laminated structure including a plurality of silicon nitride films, or a laminated structure including a plurality of silicon oxynitride films.

The inorganic insulating film 84 may have a laminated structure including at least two among a silicon oxide film, a silicon nitride film, and a silicon oxynitride film that are laminated together in an arbitrary order. The inorganic insulating film 84 may have a single layer structure constituted of a silicon oxide film, a silicon nitride film, or a silicon oxynitride film. In this embodiment, the inorganic insulating film 84 has a single layer structure constituted of a silicon nitride film. In other words, the inorganic insulating film 84 is constituted of an insulator differing from that of the interlayer insulating film 60. The thickness of the inorganic insulating film 84 may be not less than 0.1 μm and not more than 5 μm. Preferably, the thickness of the inorganic insulating film 84 is not less than 1 μm and not more than 3 μm.

The organic insulating film 85 is lower in rigidity than the inorganic insulating film 84. In other words, the organic insulating film 85 is smaller in elasticity modulus than the inorganic insulating film 84, and functions as a cushioning material against an external force. The organic insulating film 85 protects the SiC chip 2, the gate principal surface electrode 71, the gate wiring electrode 72, the source principal surface electrode 73, and so on from an external force.

Preferably, the organic insulating film 85 includes a photosensitive resin. The photosensitive resin may be a negative type or a positive type. The organic insulating film 85 may include at least one among a polyimide film, a polyamide film, and a polybenzoxazole film. In this embodiment, the organic insulating film 85 includes a polybenzoxazole film. The thickness of the organic insulating film 85 may be not less than 1 μm and not more than 50 μm. Preferably, the thickness of the organic insulating film 85 exceeds the thickness of the inorganic insulating film 84. Preferably, the thickness of the organic insulating film 85 is not less than 5 μm and not more than 20 μm.

The SiC semiconductor device 1 includes a drain electrode 91 that covers the second principal surface 4. The drain electrode 91 covers the whole area of the second principal surface 4, and is continuous to the first to fourth side surfaces 5A to 5D. The drain electrode 91 is electrically connected to the drain region 6 (second principal surface 4). In detail, the drain electrode 91 forms an ohmic contact with the drain region 6 (second principal surface 4).

In this embodiment, the drain electrode 91 includes a Ti film 92, a Ni film 93, a Pd film 94, an Au film 95, and an Ag film 96 that are laminated together in this order from the second principal surface 4 side. It suffices that the drain electrode 91 includes, at least, the Ti film 92, and the presence or absence of each of the Ni film 93, the Pd film 94, the Au film 95, and the Ag film 96 is arbitrary. As an example, the drain electrode 91 may have a laminated structure including the Ti film 92, the Ni film 93, and the Au film 95.

As described above, the SiC semiconductor device 1 includes the SiC chip 2 (semiconductor chip), the n type drift region 7, the p type body region 21, the n type source region 22, the plurality of trench source structures 33, the p type body connection region 51, and the n type source connection region 52. The SiC chip 2 has the first principal surface 3. The drift region 7 is formed at the surface layer portion of the first principal surface 3. The body region 21 is formed at the surface layer portion of the drift region 7. The source region 22 is formed at the surface layer portion of the body region 21.

The plurality of trench source structures 33 are formed at the first principal surface 3 so as to cross the source region 22 and the body region 21 and so as to reach the drift region 7, and are arranged at the first principal surface 3 with intervals therebetween in the first direction X. The body connection region 51 is formed in a region between two of the trench source structures 33 that are adjacent in the surface layer portion of the body region 21 so as to be electrically connected to the body region 21. The source connection region 52 is formed in a region between two of the trench source structures 33 that are adjacent in a region differing from the body connection region 51 in the surface layer portion of the body region 21 so as to be electrically connected to the source region 22.

According to this SiC semiconductor device 1, the trench source structure 33, the body connection region 51, and the source connection region 52 are formed so as to be arranged in the first direction X. Therefore, it is made unnecessary to form the body connection region 51 and the source connection region 52 so as to adjoin the second direction Y intersecting the first direction X.

This makes it possible to prevent enlargement in the second direction Y caused by the trench source structure 33, the body connection region 51, and the source connection region 52. Additionally, the body connection region 51 and the source connection region 52 are not required to be placed so as to be adjacent to each other in the second direction Y, and therefore it is possible to moderate both an alignment margin of the body connection region 51 and an alignment margin of the source connection region 52. Therefore, it is possible to provide a SiC semiconductor device 1 capable of contributing to miniaturization.

Preferably, the source connection region 52 faces the body connection region 51 in the first direction X with the trench source structure 33 between the source connection region 52 and the body connection region 51. Preferably, the plurality of trench source structures 33 are each formed in a belt shape extending in the first direction X.

Preferably, the body connection region 51 has a p type impurity concentration exceeding the p type impurity concentration of the body region 21. Preferably, the source region 22 has an n type impurity concentration exceeding the n type impurity concentration of the drift region 7. Preferably, the source connection region 52 has an n type impurity concentration exceeding the n type impurity concentration of the drift region 7. Preferably, the source connection region 52 is formed by using a part of the source region 22.

Preferably, the plurality of body connection regions 51 are formed, and the plurality of source connection regions 52 are formed. In this case, preferably, the plurality of source connection regions 52 are formed alternately with the plurality of body connection regions 51 along the first direction X. According to this structure, with respect to electric characteristics of the MISFET, it is possible to prevent in-plane variations caused by the plurality of body connection regions 51 and the plurality of source connection regions 52.

Preferably, the SiC semiconductor device 1 includes the plurality of trench gate structures 23. Preferably, the plurality of trench gate structures 23 are formed at the first principal surface 3 so as to cross the source region 22 and the body region 21 and so as to reach the drift region 7, and each extend in the first direction X, and are arranged at the first principal surface 3 with intervals therebetween in the second direction Y intersecting the first direction X. In this case, preferably, the plurality of trench source structures 33 are arranged at the first principal surface 3 with intervals therebetween in the first direction X between two adjacent trench gate structures 23.

According to this structure, the trench source structure 33, the body connection region 51, and the source connection region 52 are formed so as to be arranged in the first direction X between two adjacent trench gate structures 23. In other words, the body connection region 51 and the source connection region 52 are not adjacent to each other in the second direction Y between two adjacent trench gate structures 23. This makes it possible to reduce the distance between two adjacent trench gate structures 23. Therefore, it is possible to provide a SiC semiconductor device 1 capable of contributing to miniaturization.

In this structure, preferably, the body connection region 51 is formed away from the plurality of trench gate structures 23. Preferably, each of the trench source structures 33 is formed more deeply than each of the trench gate structures 23. Preferably, the plurality of trench gate structures 23 are arranged in the second direction Y with the first intervals P1 therebetween, and the plurality of trench source structures 33 are arranged in the first direction X with the second intervals P2 each of which is less than the first interval P1 (P2<P1) therebetween.

In detail, the plurality of trench gate structures 23 partition the plurality of mesa portions 24 each of which extends in the first direction X in the first principal surface 3. On the other hand, the plurality of trench source structures 33 partition the plurality of segment portions 34 each of which is constituted of a part of the mesa portion 24 in the mesa portion 24. In this structure, the body connection region 51 is formed in the segment portion 34, and the source connection region 52 is formed in the segment portion 34 different from the segment portion 34 in which the body connection region 51 is formed. According to this structure, it is possible to fix a portion forming the body connection region 51 at the segment portion 34, and it is possible to fix a portion forming the source connection region 52 at the segment portion 34. Therefore, it is possible to appropriately form both the body connection region 51 and the source connection region 52.

In this case, preferably, the plurality of segment portions 34 include the plurality of first segment portions 34A and the plurality of second segment portions 34B alternately arranged along the first direction X. In this structure, preferably, the plurality of body connection regions 51 are formed in the plurality of first segment portions 34A, and the plurality of source connection regions 52 are formed in the plurality of second segment portions 34B. According to this structure, with respect to electric characteristics of the MISFET, it is possible to prevent in-plane variations caused by the plurality of body connection regions 51 and the plurality of source connection regions 52.

Preferably, the SiC semiconductor device 1 includes the p type trench connection region 53. Preferably, the trench connection region 53 has a p type impurity concentration exceeding the p type impurity concentration of the body region 21. Preferably, the trench connection region 53 is led out from the body connection region 51 to a region along the wall surface of at least one of the trench source structures 33 in the surface layer portion of the drift region 7.

According to this structure, it is possible to transmit an electric potential (specifically, source potential) applied onto the body connection region 51 to a region on the trench source structure 33 side through the trench connection region 53. Preferably, the trench connection region 53 covers the sidewall and the bottom wall of the trench source structure 33. Additionally, preferably, the trench connection region 53 partially covers the wall surface of the trench source structure 33 so as to expose a part of the wall surface of the trench source structure 33.

Preferably, the SiC semiconductor device 1 includes the p type well region 54. Preferably, the well region 54 has a p type impurity concentration less than the p type impurity concentration of the body connection region 51. Preferably, the well region 54 is formed in a region along the wall surface of at least one of the trench source structures 33 so as to cover the trench connection region 53 in the surface layer portion of the drift region 7. According to this structure, it is possible to raise withstand voltage by means of the well region 54.

Preferably, the well region 54 has its part that covers the trench source structure 33 with the trench connection region 53 therebetween and its part that directly covers the trench source structure 33.

Preferably, the SiC semiconductor device 1 includes the source principal surface electrode 73. Preferably, the source principal surface electrode 73 is formed on the first principal surface 3, and is electrically connected to the trench source structure 33, to the body connection region 51, and to the source connection region 52 on a line connecting the trench source structure 33, the body connection region 51, and the source connection region 52 together.

Preferably, the SiC semiconductor device 1 includes the interlayer insulating film 60. Preferably, the interlayer insulating film 60 covers the first principal surface 3 and has a plurality of openings that expose the trench source structure 33, the body connection region 51, and the source connection region 52. In this case, preferably, the source principal surface electrode 73 is electrically connected to the trench source structure 33, to the body connection region 51, and to the source connection region 52 in the plurality of openings.

In this embodiment, the interlayer insulating film 60 includes the first source opening 64 that exposes the trench source structure 33, the second source opening 65 that exposes the body connection region 51, and the third source opening 66 that exposes the source connection region 52. The source principal surface electrode 73 enters the first source opening 64, the second source opening 65, and the third source opening 66 from above the interlayer insulating film 60, and is electrically connected to the trench source structure 33, to the body connection region 51, and to the source connection region 52.

The SiC semiconductor device 1 also has a structure that contributes to miniaturization from another viewpoint. In other words, the SiC semiconductor device 1 includes the SiC chip 2 (semiconductor chip), the n type drift region 7, the p type body region 21, the n type source region 22, the plurality of trench gate structures 23, the trench source structure 33, the p type body connection region 51, and the n type source connection region 52. The SiC chip 2 has the first principal surface 3. The drift region 7 is formed at the surface layer portion of the first principal surface 3. The body region 21 is formed at the surface layer portion of the drift region 7. The source region 22 is formed at the surface layer portion of the body region 21.

The plurality of trench gate structures 23 each extend in the first direction X, and are arranged with intervals therebetween in the second direction Y intersecting the first direction X, and are formed at the first principal surface 3 so as to cross the source region 22 and the body region 21 and so as to reach the drift region 7. The trench source structure 33 is formed at the first principal surface 3 so as to cross the source region 22 and the body region 21 and so as to reach the drift region 7 between two adjacent trench gate structures 23. The trench source structure 33 has one end portion on one side in the first direction X and one other end portion on the other side in the first direction X.

The body connection region 51 is formed in a region on the one end portion side of the trench source structure 33 in the surface layer portion of the body region 21 so as to be electrically connected to the body region 21. The source connection region 52 is formed in a region on the other end portion side of the trench source structure 33 in the surface layer portion of the body region 21 so as to be electrically connected to the source region 22.

According to this structure, the trench source structure 33, the body connection region 51, and the source connection region 52 are formed so as to be arranged in the first direction X between two adjacent trench gate structures 23. In other words, the body connection region 51 and the source connection region 52 are not adjacent to each other in the second direction Y in the mesa portion 24. This makes it possible to reduce the distance between two adjacent trench gate structures 23. Additionally, it is possible to moderate both an alignment margin of the body connection region 51 and an alignment margin of the source connection region 52. Therefore, it is possible to provide a SiC semiconductor device 1 capable of contributing to miniaturization.

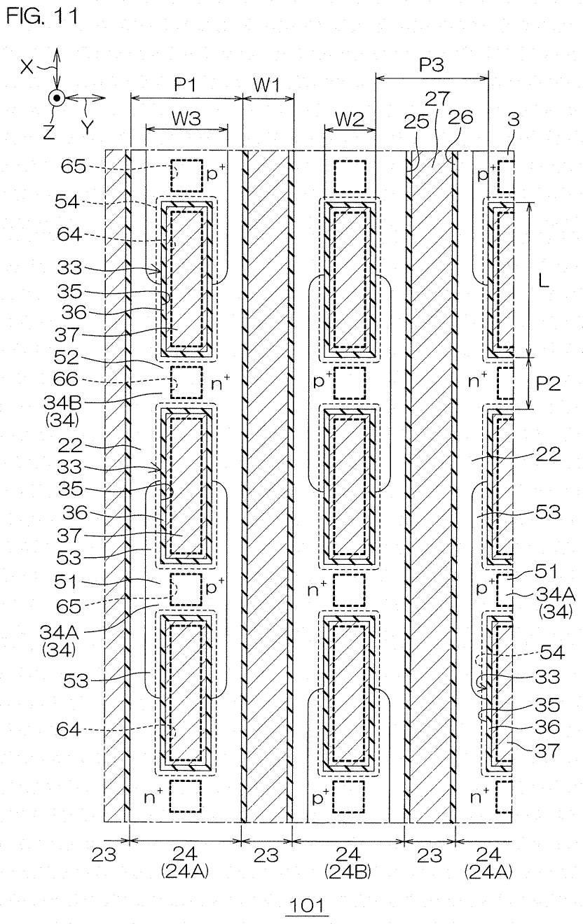

FIG. 11 corresponds to FIG. 4, and is a plan view shown to describe a structure of a SiC semiconductor device 101 according to a second preferred embodiment of the present invention. The same reference sign is hereinafter given to a structure corresponding to each structure described with respect to the SiC semiconductor device 1, and a description thereof is omitted.

Referring to FIG. 11, the plurality of mesa portions 24 include a plurality of first mesa portions 24A and a plurality of second mesa portions 24B that are alternately arranged in the second direction Y in this embodiment. In each of the first mesa portions 24A, the plurality of first segment portions 34A and the plurality of second segment portions 34B are alternately arranged along the first direction X.

In each of the second mesa portions 24B, the plurality of first segment portions 34A and the plurality of second segment portions 34B are alternately arranged along the first direction X. The plurality of first segment portions 34A of each of the second mesa portions 24B face the plurality of second segment portions 34B of each of the first mesa portions 24A in the second direction Y. The plurality of second segment portions 34B of each of the second mesa portions 24B face the plurality of first segment portions 34A of each of the first mesa portions 24A in the second direction Y.

The plurality of body connection regions 51 are formed in a region partitioned by two of the trench source structures 33 that are adjacent in the surface layer portion of the body region 21. In detail, the plurality of body connection regions 51 are formed in the plurality of first segment portions 34A, respectively, in each of the first mesa portions 24A and in each of the second mesa portions 24B.

On the other hand, the source connection region 52 is formed in a region partitioned by two of the trench source structures 33 that are adjacent in a region differing from the body connection region 51 in the surface layer portion of the body region 21. In detail, the plurality of source connection regions 52 are formed in the plurality of second segment portions 34B, respectively, in each of the first mesa portions 24A and in each of the second mesa portions 24B. In other words, the body connection regions 51 of each of the plurality of second mesa portions 24B face the plurality of source connection regions 52 of each of the first mesa portions 24A in the second direction Y. Additionally, the plurality of source connection regions 52 of each of the second mesa portions 24B face the plurality of body connection regions 51 of each of the first mesa portions 24A in the second direction Y.

As described above, the same effect as the effect described with respect to the SiC semiconductor device 1 is likewise fulfilled by the SiC semiconductor device 101.

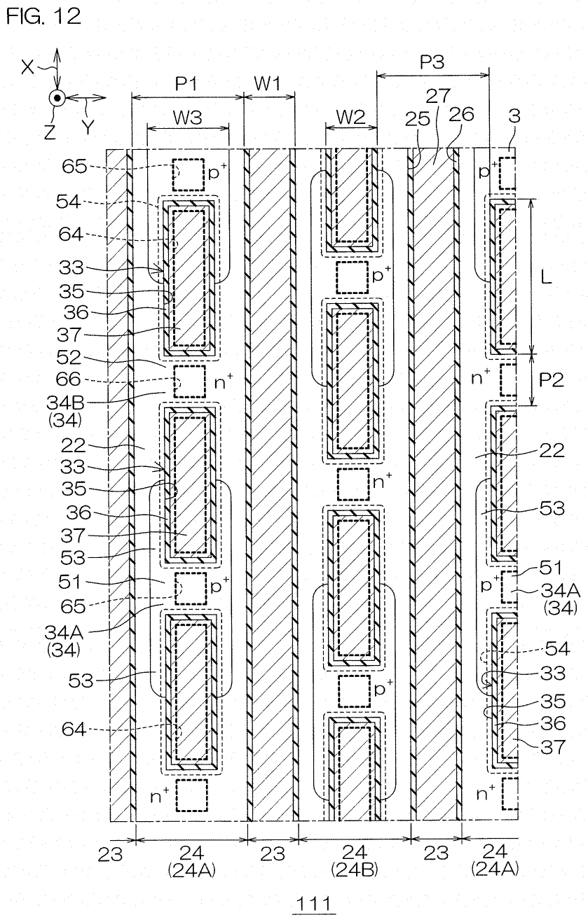

FIG. 12 corresponds to FIG. 4, and is a plan view shown to describe a structure of a SiC semiconductor device 111 according to a third preferred embodiment of the present invention. The same reference sign is hereinafter given to a structure corresponding to each structure described with respect to the SiC semiconductor device 1, and a description thereof is omitted.

Referring to FIG. 12, the plurality of mesa portions 24 include the plurality of first mesa portions 24A and the plurality of second mesa portions 24B alternately arranged in the second direction Y in this embodiment. In each of the first mesa portions 24A, the plurality of trench source structures 33 are arranged with intervals therebetween in the first direction X. The plurality of trench source structures 33 partition the plurality of segment portions 34 in each of the first mesa portions 24A. The plurality of segment portions 34 of each of the first mesa portions 24A include the plurality of first segment portions 34A and the plurality of second segment portions 34B alternately arranged along the first direction X.

In each of the second mesa portions 24B, the plurality of trench source structures 33 are arranged with intervals therebetween in the first direction X. The plurality of trench source structures 33 of each of the second mesa portions 24B are arranged in a deviated state in the first direction X from the plurality of trench source structures 33 of each of the first mesa portions 24A so as to face the plurality of segment portions 34 of each of the first mesa portions 24A in the second direction Y. In this embodiment, the plurality of trench source structures 33 of each of the second mesa portions 24B are arranged at a deviation of a half pitch in the first direction X with respect to the trench source structures 33 of each of the plurality of first mesa portions 24A. In other words, the plurality of trench source structures 33 are arranged in a staggered manner with intervals therebetween in the first direction X and in the second direction Y as a whole in a plan view.

The plurality of trench source structures 33 partition the plurality of segment portions 34 in each of the second mesa portions 24B. The plurality of segment portions 34 of each of the second mesa portions 24B include the plurality of first segment portions 34A and the plurality of second segment portions 34B alternately arranged along the first direction X. The plurality of first segment portions 34A of each of the second mesa portions 24B face the plurality of trench source structures 33 of each of the first mesa portions 24A, respectively, in the second direction Y. The plurality of second segment portions 34B of each of the second mesa portions 24B face the plurality of trench source structures 33 of each of the first mesa portions 24A, respectively, in the second direction Y.

The plurality of body connection regions 51 are formed in a region partitioned by two of the trench source structures 33 that are adjacent in the surface layer portion of the body region 21. In detail, the plurality of body connection regions 51 are formed in the plurality of first segment portions 34A, respectively, in each of the first mesa portions 24A and in each of the second mesa portions 24B. In other words, the plurality of body connection regions 51 of each of the first mesa portions 24A face the plurality of trench source structures 33 of each of the second mesa portions 24B in the second direction Y. Additionally, the plurality of body connection regions 51 of each of the second mesa portions 24B face the plurality of trench source structures 33 of each of the first mesa portions 24A in the second direction Y.

On the other hand, the plurality of source connection regions 52 are formed in a region partitioned by two of the trench source structures 33 that are adjacent in a region differing from the body connection region 51 in the surface layer portion of the body region 21. In detail, the plurality of source connection regions 52 are formed in the plurality of second segment portions 34B, respectively, in each of the first mesa portions 24A and in each of the second mesa portions 24B. In other words, the plurality of source connection regions 52 of each of the first mesa portions 24A face the plurality of trench source structures 33 of each of the second mesa portions 24B in the second direction Y. Additionally, the plurality of source connection regions 52 of each of the second mesa portions 24B face the plurality of trench source structures 33 of each of the first mesa portions 24A in the second direction Y.

The plurality of trench connection regions 53 are formed in the same manner as in the first preferred embodiment. Preferably, the plurality of trench connection regions 53 face the plurality of source connection regions 52 (second segment portion 34B) in the second direction Y.

As described above, the same effect as the effect described with respect to the SiC semiconductor device 1 is likewise fulfilled by the SiC semiconductor device 111.

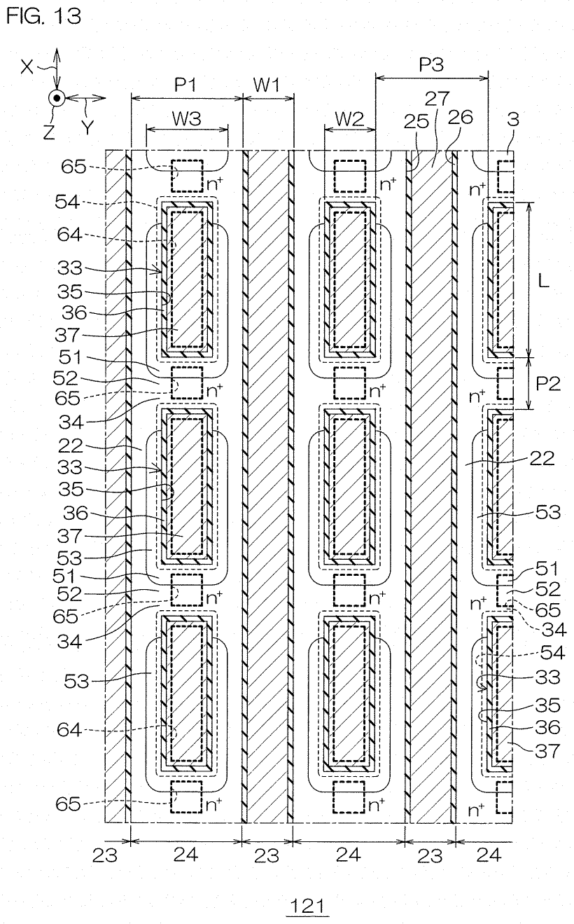

FIG. 13 corresponds to FIG. 4, and is a plan view shown to describe a structure of a SiC semiconductor device 121 according to a fourth preferred embodiment of the present invention. The same reference sign is hereinafter given to a structure corresponding to each structure described with respect to the SiC semiconductor device 1, and a description thereof is omitted.

Referring to FIG. 13, the plurality of body connection regions 51 are formed in a region partitioned by two of the trench source structures 33 that are adjacent in the surface layer portion of the body region 21. In detail, the plurality of body connection regions 51 are each formed at the surface layer portion of the body region 21 at a distance from the trench source structure 33 on one side toward the trench source structure 33 on the other side in the plurality of segment portions 34. Each of the body connection regions 51 is in contact with the trench source structure 33 on the other side in the first direction X. In other words, each of the body connection regions 51 faces the source electrode 37 with the source insulating film 36 of the trench source structure 33 on the other side between the body connection region 51 and the source electrode 37 in each of the segment portions 34.

On the other hand, the plurality of source connection regions 52 are formed in a region partitioned by two of the trench source structures 33 that are adjacent in a region differing from the body connection region 51 in the surface layer portion of the body region 21. In detail, each of the source connection regions 52 is formed in the same segment portion 34 as each of the body connection regions 51 so as to coexist with each of the body connection regions 51.

In detail, the plurality of source connection regions 52 are each formed at the surface layer portion of the body region 21 at a distance from the trench source structure 33 on the other side toward the trench source structure 33 on one side in the plurality of segment portions 34. The plurality of source connection regions 52 are adjacent to the plurality of body connection regions 51 from the first direction X. Each of the source connection regions 52 is in contact with the trench source structure 33 on one side in the first direction X. Each of the source connection regions 52 faces the source electrode 37 with the source insulating film 36 of the trench source structure 33 on one side between the source connection region 52 and the source electrode 37 in each of the segment portions 34.

The plurality of trench connection regions 53 are each led out from the plurality of body connection regions 51 to the wall surface of an adjacent trench source structure 33. In this embodiment, one trench connection region 53 is led out from each of the body connection regions 51 toward the wall surface of an adjacent trench source structure 33. In other words, the plurality of trench connection regions 53 are formed in a one-to-one correspondence relationship with respect to the plurality of trench source structures 33, respectively, in a plan view. In this embodiment, each of the trench connection regions 53 crosses the intermediate portion of the trench source structure 33 in a plan view.

Each of the trench connection regions 53 partially covers the wall surface of the trench source structure 33 so as to expose a part of the wall surface of the trench source structure 33. In detail, each of the trench connection regions 53 is formed at a distance from the segment portion 34 on the source connection region 52 side toward the segment portion 34 on the body connection region 51 side.

Therefore, each of the trench connection regions 53 exposes the source connection region 52. Additionally, each of the trench connection regions 53 exposes the end portion (sidewall and bottom wall) on the source connection region 52 side of the trench source structure 33. Each of the trench connection regions 53 is formed at a distance inwardly from two adjacent trench gate structures 23 so as to expose a part of the source region 22 from the first principal surface 3 with respect to the second direction Y.

In this embodiment, the interlayer insulating film 60 does not include the third source opening 66, and includes the plurality of first source openings 64 and the plurality of second source openings 65. In this embodiment, each of the second source openings 65 is formed as an opening for the body connection region 51 and for the source connection region 52. In other words, each of the second source openings 65 is formed in a one-to-one correspondence relationship with respect to each of the segment portions 34, and exposes each of the body connection regions 51 and each of the source connection regions 52.

With respect to each of the mesa portions 24, the plurality of second source openings 65 are formed at a distance from the plurality of first source openings 64 in the first direction X, and face the plurality of first source openings 64, respectively, in the first direction X. The planar shape of each of the second source openings 65 is arbitrary, and each of the second source openings 65 may be formed in a square shape, a rectangular shape, a circular shape, etc.

As described above, the same effect as the effect described with respect to the SiC semiconductor device 1 is likewise fulfilled by the SiC semiconductor device 121. Of course, a structure in which the body connection region 51 and the source connection region 52 coexist with each other in one segment portion 34 is also applicable to the second and third preferred embodiments.

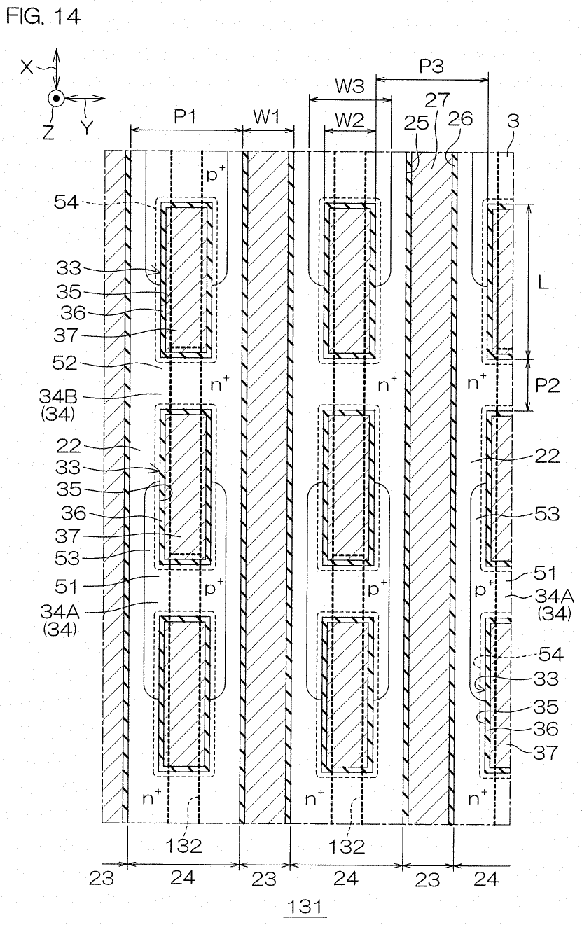

FIG. 14 corresponds to FIG. 4, and is a plan view shown to describe a structure of a SiC semiconductor device 131 according to a fifth preferred embodiment of the present invention. The same reference sign is hereinafter given to a structure corresponding to each structure described with respect to the SiC semiconductor device 1, and a description thereof is omitted.

Referring to FIG. 14, the first source opening 64, the second source opening 65, and the third source opening 66 are integrally formed in the interlayer insulating film 60 according to the SiC semiconductor device 131. In other words, the interlayer insulating film 60 has a plurality of linear source openings 132 extending in the first direction X along the plurality of mesa portions 24, respectively.

Each of the source openings 132 collectively exposes the plurality of trench source structures 33 (source electrodes 37), the plurality of body connection regions 51, and the plurality of source connection regions 52 in each of the mesa portions 24. In this case, the source principal surface electrode 73 enters the plurality of source openings 132 from above the interlayer insulating film 60, and is electrically connected to the trench source structure 33, to the body connection region 51, and to the source connection region 52 of the plurality of mesa portions 24.

As described above, the same effect as the effect described with respect to the SiC semiconductor device 1 is likewise fulfilled by the SiC semiconductor device 131. Of course, a structure in which the interlayer insulating film 60 has the plurality of source openings 132 is also applicable to the second to fourth preferred embodiments. In the fourth preferred embodiment, preferably, the source opening 132 is employed in place of the plurality of first source openings 64 and the plurality of second source openings 65.

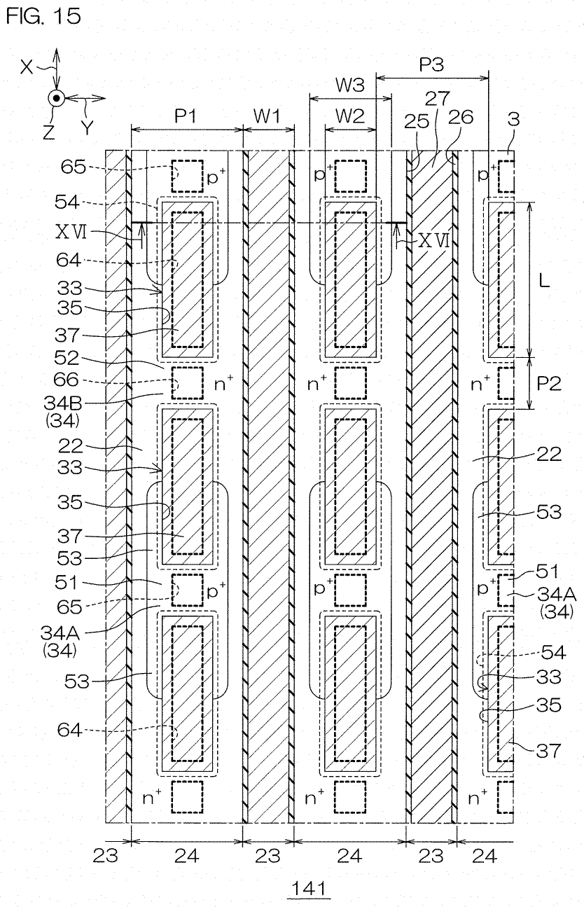

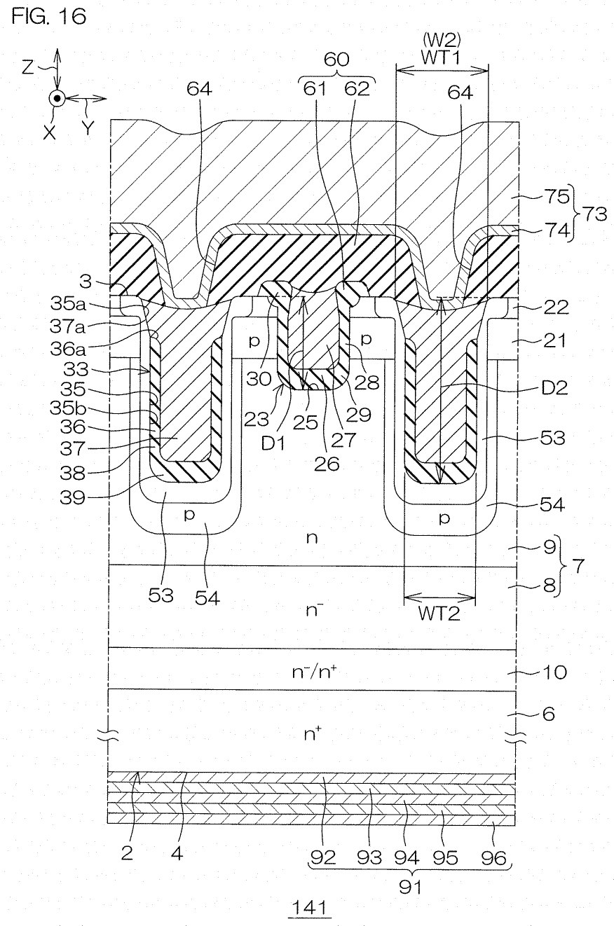

FIG. 15 corresponds to FIG. 4, and is a plan view shown to describe a structure of a SiC semiconductor device 141 according to a sixth preferred embodiment of the present invention. FIG. 16 is a cross-sectional view along line XVI-XVI shown in FIG. 15. The same reference sign is hereinafter given to a structure corresponding to each structure described with respect to the SiC semiconductor device 1, and a description thereof is omitted.

Referring to FIG. 15 and FIG. 16, the SiC semiconductor device 141 has a trench source structure 33 that is constituted of a structure different from the trench source structure 33 of the SiC semiconductor device 1. In detail, the source trench 35 of each of the trench source structures 33 includes a first trench portion 35a on the opening side and a second trench portion 35b on the bottom wall side. The first trench portion 35a has a first trench width WT1 with respect to the second direction Y. The first trench width WT1 is a second width W2 of the trench source structure 33. The first trench portion 35a may be formed in a tapered shape in which the first trench width WT1 becomes narrower toward the bottom wall side.

The first trench portion 35a exposes the body region 21 and the source region 22. Preferably, the first trench portion 35a is formed in a region on the first principal surface 3 side with respect to the bottom wall of the gate trench 25. In other words, preferably, the depth of the first trench portion 35a is less than the first depth D1 of the trench gate structure 23. Of course, the first trench portion 35a may be formed more deeply than the trench gate structure 23. The depth of the first trench portion 35a may be not less than 0.1 μm and not more than 2 μm.

The second trench portion 35b exposes the drift region 7. The second trench portion 35b is in communication with the first trench 35a, and extends from the first trench portion 35a toward the bottom portion of the drift region 7 (high concentration region 9). In this embodiment, the second trench portion 35b crosses the bottom wall of the trench gate structure 23. The second trench portion 35b may be formed in a vertical shape having a substantially uniform opening width. The second trench portion 35b may be formed in a tapered shape having an opening width that becomes narrower toward the bottom wall.

Preferably, the depth of the second trench portion 35b based on the first trench portion 35a exceeds the first depth D1 of the trench gate structure 23. The second trench portion 35b has a second trench width WT2 less than the first trench width WT1 (WT2<WT1) with respect to the second direction Y. The second trench width WT2 may be not less than 0.5 μm and be less than 3 μm.

The source insulating film 36 is formed in a film shape on the inner wall of the source trench 35, and defines a recessed space in the source trench 35. In detail, the source insulating film 36 has a window portion 36a that exposes the first trench portion 35a, and defines a recessed space in the second trench portion 35b.

In this embodiment, the source insulating film 36 includes the first portion 38 and the second portion 39, and does not include the third portion 40. The first portion 38 covers the sidewall of the source trench 35 (second trench portion 35b), and defines the window portion 36a on the opening portion side (first trench portion 35a side) of the source trench 35. The second portion 39 covers the bottom wall of the source trench 35 (second trench portion 35b).

The thickness of the first portion 38 may be not less than 10 nm and not more than 250 nm. The second portion 39 may have a thickness exceeding the thickness of the first portion 38. The thickness of the second portion 39 may be not less than 50 nm and not more than 500 nm. Of course, the source insulating film 36 having a uniform thickness may be formed.

The source electrode 37 is embedded in the source trench 35 with the source insulating film 36 between the source electrode 37 and the source trench 35. In detail, the source electrode 37 is embedded in the first trench portion 35a and in the second trench portion 35b with the source insulating film 36 between the source electrode 37 and the first and second trench portions 35a and 35b, and has a contact portion 37a that is in contact with to the first trench portion 35a exposed from the window portion 36a.

The contact portion 37a is electrically connected to the body region 21 and to the source region 22 in the window portion 36a. In other words, the contact portion 37a allows the body region 21 and the source region 22 to be source grounded inside the source trench 35. The source electrode 37 has an electrode surface exposed from the source trench 35. The electrode surface of the source electrode 37 is formed in a curved shape hollowed toward the bottom wall of the source trench 35.

Each of the body connection regions 51 is electrically connected to the contact portion 37a of the source electrode 37 exposed from the first trench portion 35a in each of the segment portions 34 (first segment portion 34A). Hence, each of the body connection regions 51 is source grounded inside the SiC chip 2. Each of the body connection regions 51 may cover a part of the second trench portion 35b, and may face the source electrode 37 with a part of the source insulating film 36 between the body connection region 51 and the source electrode 37.

Each of the source connection regions 52 is electrically connected to the contact portion 37a of the source electrode 37 exposed from the first trench portion 35a in each of the segment portions 34 (second segment portion 34B). Hence, each of the source connection regions 52 is source grounded inside the SiC chip 2. Each of the source connection regions 52 may cover a part of the second trench portion 35b, and may face the source electrode 37 with a part of the source insulating film 36 between the source connection region 52 and the source electrode 37.

Each of the trench connection regions 53 covers the first trench portion 35a and the second trench portion 35b of each of the trench source structures 33. Each of the trench connection regions 53 is electrically connected to the contact portion 37a of the source electrode 37 exposed from the first trench portion 35a. Hence, each of the trench connection regions 53 is source grounded inside the SiC chip 2. Each of the trench connection regions 53 faces the source electrode 37 with a part of the source insulating film 36 between the trench connection region 53 and the source electrode 37 on the second trench portion 35b side.

In this embodiment, each of the well regions 54 is electrically connected to the source electrode 37 (contact portion 37a) through the body region 21, the source region 22, the body connection region 51, the source connection region 52, and the trench connection region 53.

Other structures are identical with those of the aforementioned SiC semiconductor device 1, and therefore a descriptions of these structures is omitted. As described above, the same effect as the effect described with respect to the SiC semiconductor device 1 is likewise fulfilled by the SiC semiconductor device 141. Additionally, in the SiC semiconductor device 141, the source electrode 37 has the contact portion 37a exposed from the sidewall of the source trench 35 in a region on the opening side of the source trench 35.

Additionally, the SiC semiconductor device 141 includes the body connection region 51 electrically connected to the contact portion 37a of the source electrode 37. This enables the body connection region 51 to be source grounded inside the SiC chip 2. Additionally, the SiC semiconductor device 141 includes the source connection region 52 electrically connected to the contact portion 37a of the source electrode 37. This enables the source connection region 52 to be source grounded inside the SiC chip 2.

As thus described, with the SiC semiconductor device 141, the contact portion 37a of the source electrode 37 enables a to-be-source-grounded semiconductor region to be source grounded inside the SiC chip 2. In this embodiment, the body region 21, the source region 22, the body connection region 51, the source connection region 52, the trench connection region 53, and the well region 54 are electrically connected to the source electrode 37 inside the SiC chip 2. The thus formed structure is effective in easing the alignment margin of a structure in the active region 11. The trench source structure 33 of the SiC semiconductor device 141 is also applicable to the second to fifth preferred embodiments.

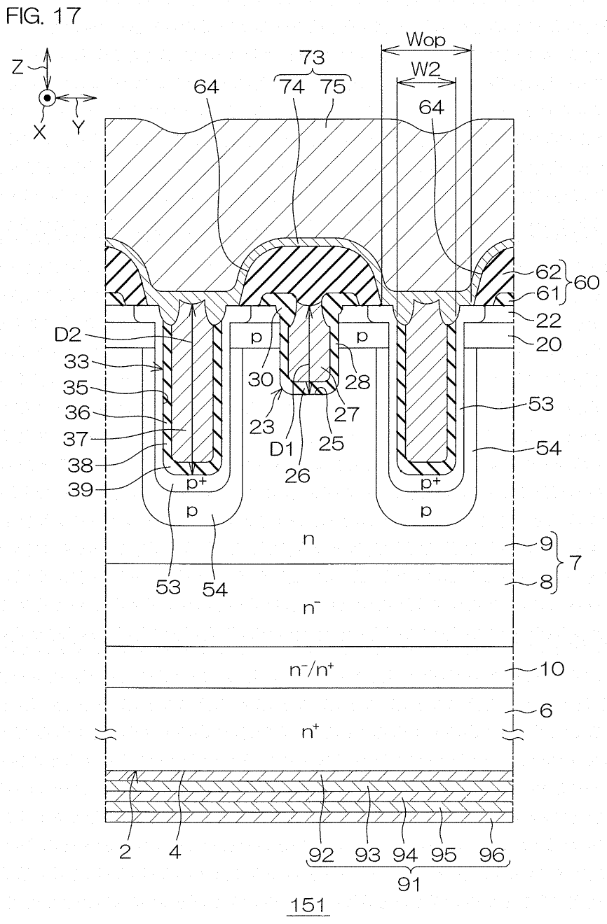

FIG. 17 corresponds to FIG. 6, and is a cross-sectional view shown to describe a structure of a SiC semiconductor device 151 according to a seventh preferred embodiment of the present invention. The same reference sign is hereinafter given to a structure corresponding to each structure described with respect to the SiC semiconductor device 1, and a description thereof is omitted.

Referring to FIG. 17, in the SiC semiconductor device 151, the source insulating film 36 includes the first portion 38 and the second portion 39, and does not include the third portion 40. The first portion 38 of the source insulating film 36 covers the sidewall of the source trench 35 at a distance from an opening end of the source trench 35 toward the bottom wall side so as to expose the surface layer portion of the first principal surface 3 from the opening end of the source trench 35. A part of the sidewall of the source electrode 37 is exposed from the source insulating film 36 in the opening end of the source trench 35.

The source region 22 may be exposed from the sidewall of the source trench 35 in the opening end of the source trench 35. The body connection region 51 may be exposed from the sidewall of the source trench 35 in the opening end of the source trench 35. The source connection region 52 may be exposed from the sidewall of the source trench 35 in the opening end of the source trench 35. The trench connection region 53 may be exposed from the sidewall of the source trench 35 in the opening end of the source trench 35.

In this embodiment, each of the first source openings 64 has an opening width Wop exceeding the second width W2 of the trench source structure 33 (W2<Wop). The opening width Wop is the width of the first source opening 64 along the second direction Y. Preferably, each of the first source openings 64 exposes at least the source region 22, the source electrode 37, and the trench connection region 53. Each of the first source openings 64 may expose the body connection region 51 and the source connection region 52.

Each of the second source openings 65 may have an opening width Wop exceeding the second width W2 of the trench source structure 33 in the same way as the first source opening 64. Each of the third source openings 66 may have an opening width Wop exceeding the second width W2 of the trench source structure 33 in the same way as the first source opening 64.

The source principal surface electrode 73 enters the plurality of first source openings 64, the plurality of second source openings 65, and the plurality of third source openings 66 from above the interlayer insulating film 60, and is electrically connected to the plurality of source regions 22, to the plurality of source electrodes 37, to the plurality of body connection regions 51, to the plurality of source connection regions 52, and to the plurality of trench connection regions 53. The source principal surface electrode 73 (specifically, first electrode film 74) covers a part of the sidewall of the source electrode 37 in each of the source trenches 35.

As described above, the same effect as the effect described with respect to the SiC semiconductor device 1 is likewise fulfilled by the SiC semiconductor device 151. A configuration in which the first source opening 64, the second source opening 65, and the third source opening 66 each have an opening width Wop exceeding the second width W2 of the trench source structure 33 is also applicable to the second to sixth preferred embodiments besides the first preferred embodiment. For example, in the SiC semiconductor device 131 of the fifth preferred embodiment, the linear source opening 132 may have an opening width Wop exceeding the second width W2 of the trench source structure 33.

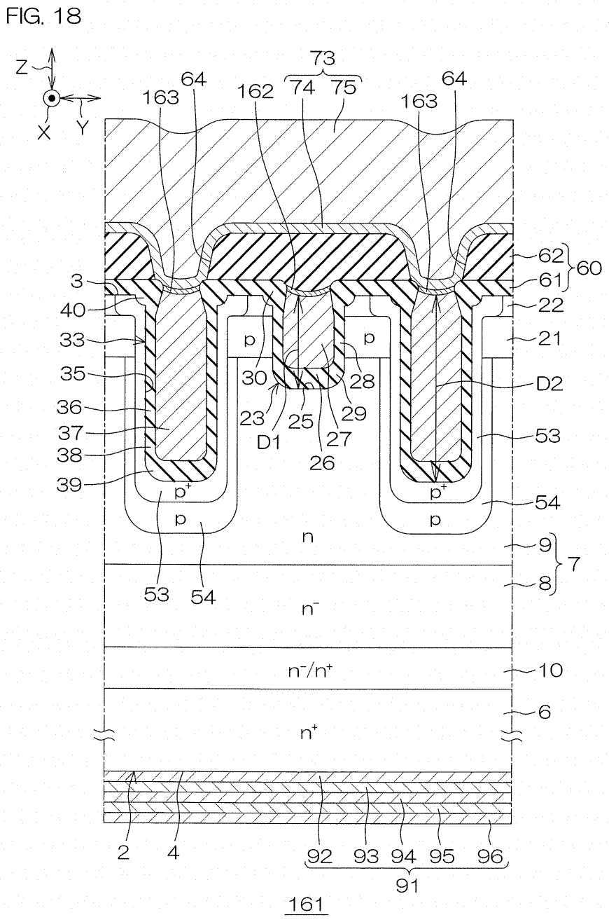

FIG. 18 corresponds to FIG. 6, and is a cross-sectional view shown to describe a structure of a SiC semiconductor device 161 according to an eighth preferred embodiment of the present invention. The same reference sign is hereinafter given to a structure corresponding to each structure described with respect to the SiC semiconductor device 1, and a description thereof is omitted.

Referring to FIG. 18, the SiC semiconductor device 161 includes the gate electrode 27 including a p type polysilicon that is doped with a p type impurity. In detail, the gate electrode 27 is constituted of p type polysilicon. The p type impurity concentration of the p type polysilicon of the gate electrode 27 may be not less than 1.0×10¹⁸ cm⁻³ and not more than 1.0×10²² cm⁻³. The sheet resistance of the gate electrode 27 may be not less than 10Ω/□ and not more than 500 Ω/□.

The SiC semiconductor device 161 includes the source electrode 37 including the same conductive material as the gate electrode 27. In other words, the source electrode 37 includes p type polysilicon that is doped with a p type impurity. In detail, the source electrode 37 is constituted of p type polysilicon. The p type impurity concentration of the p type polysilicon of the source electrode 37 may be not less than 1.0×10¹⁸ cm⁻³ and not more than 1.0×10²² cm⁻³. The sheet resistance of the source electrode 37 may be not less than 10Ω/□ and not more than 500 Ω/□.

The SiC semiconductor device 161 includes a first low resistance layer 162 that covers the gate electrode 27. The first low resistance layer 162 covers the gate electrode 27 in the gate trench 25. In other words, the first low resistance layer 162 forms a part of the trench gate structure 23. The first low resistance layer 162 is in contact with to the gate insulating film 26 in the gate trench 25. Preferably, the first low resistance layer 162 is in contact with a corner portion of the gate insulating film 26 (i.e., third portion 30).

The first low resistance layer 162 includes a conductive material having a sheet resistance less than the sheet resistance of the gate electrode 27. The sheet resistance of the first low resistance layer 162 may be not less than 0.01Ω/□ and not more than 10Ω/□. Preferably, the first low resistance layer 162 has a specific resistance of not less than 10 μΩ·cm and not more than 110 μΩ·cm. In this embodiment, the first low resistance layer 162 is constituted of a polycide layer (specifically, a p type polycide layer) with which a surface layer portion of the gate electrode 27 is silicided with a metal. In other words, the first low resistance layer 162 is formed integrally with the gate electrode 27 in the surface layer portion of the gate electrode 27, and forms an electrode surface of the gate electrode 27.

The first low resistance layer 162 may include at least one among TiSi, TiSi₂, NiSi, CoSi, CoSi₂, MoSi₂, and WSi₂. Preferably, the first low resistance layer 162 includes at least one among NiSi, CoSi₂, and TiSi₂. Particularly preferably, the first low resistance layer 162 is constituted of CoSi₂.

The SiC semiconductor device 161 includes a second low resistance layer 163 that covers the source electrode 37. The second low resistance layer 163 covers the source electrode 37 in the source trench 35. In other words, the second low resistance layer 163 forms a part of the trench source structure 33. The second low resistance layer 163 is in contact with the source insulating film 36 in the source trench 35. Preferably, the second low resistance layer 163 is in contact with a corner portion of the source insulating film 36 (i.e., third portion 40).

The second low resistance layer 163 includes a conductive material having a sheet resistance less than the sheet resistance of the source electrode 37. The sheet resistance of the second low resistance layer 163 may be not less than 0.01Ω/□ and not more than 10Ω/□. Preferably, the second low resistance layer 163 has a specific resistance of not less than 10 μΩ·cm and not more than 110 μΩ·cm. In this embodiment, the second low resistance layer 163 is constituted of a polycide layer (specifically, a p type polycide layer) with which a surface layer portion of the source electrode 37 is silicided with a metal. In other words, the second low resistance layer 163 is formed integrally with the source electrode 37 in the surface layer portion of the source electrode 37, and forms an electrode surface of the source electrode 37.

The second low resistance layer 163 may include at least one among TiSi, TiSi₂, NiSi, CoSi, CoSi₂, MoSi₂, and WSi₂. Preferably, the second low resistance layer 163 includes at least one among NiSi, CoSi₂, and TiSi₂. Particularly preferably, the second low resistance layer 163 is constituted of CoSi₂. Preferably, the second low resistance layer 163 is constituted of the same material as the first low resistance layer 162.

As described above, the same effect as the effect described with respect to the SiC semiconductor device 1 is likewise fulfilled by the SiC semiconductor device 161. Additionally, the SiC semiconductor device 161 includes the gate electrode 27 including p type polysilicon and the first low resistance layer 162 that covers the gate electrode 27.

According to the gate electrode 27 including p type polysilicon, the sheet resistance in the gate trench 25 increases in comparison with the case of n type polysilicon, and, on the other hand, it is possible to raise a gate threshold voltage Vth by about 1 V. According to the first low resistance layer 162, it is possible to reduce parasitic resistance in the gate trench 25 while preventing a decrease of the gate threshold voltage Vth. Therefore, with the SiC semiconductor device 161, it is possible to reduce parasitic resistance in the gate trench 25 while raising the gate threshold voltage Vth.

The first low resistance layer 162 and the second low resistance layer 163 according to the SiC semiconductor device 161 are also applicable to the second to seventh preferred embodiments besides the first preferred embodiment. If the first low resistance layer 162 and the second low resistance layer 163 are applied to the SiC semiconductor device 141 according to the sixth preferred embodiment, the second low resistance layer 163 forms the contact portion 37a in contact with the first trench portion 35a together with the source electrode 37. In other words, the second low resistance layer 163 allows the body region 21 and the source region 22 to be source grounded inside the source trench 35.

The preferred embodiment of the present invention can be carried out in still other embodiments. For example, although with each of the preferred embodiments, an example in which the first direction X is the m axis direction of the SiC monocrystal and the second direction Y is the a axis direction of the SiC monocrystal was described, the first direction X may be the a axis direction of the SiC monocrystal, and the second direction Y may be the m axis direction of the SiC monocrystal. In other words, the first side surface 5A and the second side surface 5B (two short sides of the SiC chip 2) may be formed by the m plane of the SiC monocrystal, and the third side surface 5C and the fourth side surface 5D (two long sides of the SiC chip 2) may be formed by the a plane of the SiC monocrystal. In this case, the off direction may be the a axis direction of the SiC monocrystal. A specific arrangement of this case can be obtained by replacing the m axis direction according to the first direction X with the a axis direction and by replacing the a axis direction according to the second direction Y with the m axis direction in the above description and the accompanying drawings.

In each of the preferred embodiments described above, the gate pad electrode serving as a terminal electrode may be formed on the gate principal surface electrode 71, and the source pad electrode serving as a terminal electrode may be formed on the source principal surface electrode 73. In this case, preferably, the gate pad electrode includes a Ni plating film that covers the gate principal surface electrode 71. The gate pad electrode may include a Pd plating film and an Au plating film laminated together in this order from the Ni plating film side. Additionally, preferably, the source pad electrode includes a Ni plating film that covers the source principal surface electrode 73. The source pad electrode may include a Pd plating film and an Au plating film laminated together in this order from the Ni plating film side.

In each of the preferred embodiments described above, a Si chip constituted of a Si monocrystal may be employed in place of the SiC chip 2. In other words, a Si semiconductor device may be employed in place of the SiC semiconductor devices 1, 101, 111, 121, 131, 141, 151, and 161 according to each of the preferred embodiments.

Although with each of the preferred embodiments, an example in which the first conductivity type is an n type and the second conductivity type is a p type was described, the first conductivity type may be a p type, and the second conductivity type may be an n type. A specific arrangement of this case can be obtained by replacing the n type region with a p type region and by replacing the p type region with an n type region in the above description and the accompanying drawings.

In each of the preferred embodiments, a p type collector region may be employed in place of the n type drain region 6. According to this structure, it is possible to provide an IGBT (Insulated Gate Bipolar Transistor) in place of the MISFET. A specific arrangement of this case can be obtained by replacing a “source” of the MISFET with an “emitter” of the IGBT and by replacing a “drain” of the MISFET with a “collector” of the IGBT in the above description.

Examples of features extracted from this description and from the drawings will be hereinafter shown. [A1] to [A20] and [B1] to [B20] mentioned below provide semiconductor devices each of which is capable of contributing to miniaturization.

[A1] A semiconductor device including a semiconductor chip (2) having a principal surface (3), a first-conductivity-type (n type) drift region (7) formed at a surface layer portion of the principal surface (3), a second-conductivity-type (p type) body region (21) formed at a surface layer portion of the drift region (7), a first-conductivity-type (n type) source region (22) formed at a surface layer portion of the body region (21), a plurality of trench source structures (33) that are formed at the principal surface (3) so as to cross the source region (22) and the body region (21) and so as to reach the drift region (7) and that are arranged with intervals therebetween in a first direction (X), a second-conductivity-type (p type) body connection region (51) formed in a region between two of the trench source structures (33) that are adjacent in the surface layer portion of the body region (21) so as to be electrically connected to the body region (21), and a first-conductivity-type (n type) source connection region (52) formed in a region between two of the trench source structures (33) that are adjacent in a region differing from the body connection region (51) in the surface layer portion of the body region (21) so as to be electrically connected to the source region (22).

[A2] The semiconductor device according to A1, wherein the source connection region (52) faces the body connection region (51) in the first direction (X) with the trench source structure (33) between the source connection region (52) and the body connection region (51).

[A3] The semiconductor device according to A1 or A2, wherein a plurality of the trench source structures (33) are each formed in a belt shape extending in the first direction (X).

[A4] The semiconductor device according to any one of A1 to A3, wherein the body connection region (51) has an impurity concentration exceeding an impurity concentration of the body region (21).

[A5] The semiconductor device according to any one of A1 to A4, wherein the source region (22) has an impurity concentration exceeding an impurity concentration of the drift region (7), and the source connection region (52) has an impurity concentration exceeding the impurity concentration of the drift region (7).

[A6] The semiconductor device according to any one of A1 to A5, wherein the source connection region (52) is formed by using a part of the source region (22).

[A7] The semiconductor device according to any one of A1 to A6, wherein a plurality of the body connection regions (51) are formed, and a plurality of the source connection regions (52) are formed.

[A8] The semiconductor device according to A7, wherein a plurality of the source connection regions (52) are formed alternately with a plurality of the body connection regions (51) along the first direction (X).

[A9] The semiconductor device according to any one of A1 to A8, further including a plurality of trench gate structures (23) that are formed at the principal surface (3) so as to cross the source region (22) and the body region (21) and so as to reach the drift region (7), each of which extends in the first direction (X), and that are arranged at the principal surface (3) with intervals therebetween in a second direction (Y) intersecting the first direction (X), wherein a plurality of the trench source structures (33) are arranged with intervals therebetween in the first direction (X) between two of the trench gate structures (23) that are adjacent.

[A10] The semiconductor device according to A9, wherein the body connection region (51) is formed at a distance from a plurality of the trench gate structures (23).

[A11] The semiconductor device according to A9 or A10, wherein each of the trench source structures (33) is formed more deeply than each of the trench gate structures (23).

[A12] The semiconductor device according to any one of A9 to A11, wherein a plurality of the trench gate structures (23) partition a plurality of mesa portions (24) each of which extends in the first direction (X) at the principal surface (3), a plurality of the trench source structures (33) partition a plurality of segment portions (34) constituted of a part of the mesa portion (24) in the mesa portion (24), the body connection region (51) is formed in the segment portion (34), and the source connection region (52) is formed in the segment portion (34) differing from the segment portion (34) in which the body connection region (51) is formed.

[A13] The semiconductor device according to A12, wherein a plurality of the segment portions (34) include a plurality of first segment portions (34A) and a plurality of second segment portions (34B) alternately arranged along the first direction (X), a plurality of the body connection regions (51) are formed in a plurality of the first segment portions (34A), and a plurality of the source connection regions (52) are formed in a plurality of the second segment portions (34B).

[A14] The semiconductor device according to any one of A9 to A13, wherein a plurality of the trench gate structures (23) are arranged with first intervals (P1) therebetween in the second direction (Y), and a plurality of the trench source structures (33) are arranged with second intervals (P2) each of which is less than the first interval (P1) therebetween in the first direction (X).

[A15] The semiconductor device according to any one of A1 to A14, further including a second-conductivity-type (p type) trench connection region (53) led out from the body connection region (51) to a region along a wall surface of at least one of the trench source structures (33) in the surface layer portion of the drift region (7).

[A16] The semiconductor device according to A15, wherein the trench connection region (53) covers a sidewall and a bottom wall of the trench source structure (33).

[A17] The semiconductor device according to A15 or A16, wherein the trench connection region (53) partially covers the wall surface of the trench source structure (33) so as to expose a part of the wall surface of the trench source structure (33).

[A18] The semiconductor device according to any one of A15 to A17, further including a second-conductivity-type (p type) well region (54) that is formed in a region along the wall surface of at least one of the trench source structures (33) so as to cover the trench connection region (53) in the surface layer portion of the drift region (7) and that is lower in impurity concentration than the body connection region (51).

[A19] The semiconductor device according to A18, wherein the well region (54) has a part that covers the trench source structure (33) with the trench connection region (53) between the part of the well region (54) and the trench source structure (33) and a part that directly covers the trench source structure (33).

[A20] The semiconductor device according to any one of A1 to A19, further including a source principal surface electrode (73) that is formed on the principal surface (3) and that is electrically connected to the trench source structure (33), to the body connection region (51), and to the source connection region (52) on a line connecting the trench source structure (33), the body connection region (51), and the source connection region (52) together.

[B1] A SiC semiconductor device including a SiC chip (2) that has a principal surface (3), a first-conductivity-type (n type) drift region (7) formed at a surface layer portion of the principal surface (3), a second-conductivity-type (p type) body region (21) formed at a surface layer portion of the drift region (7), a first-conductivity-type (n type) source region (22) formed at a surface layer portion of the body region (21), a plurality of trench gate structures (23) each of which extends in a first direction (X) along the principal surface (3), that are arranged with intervals therebetween in a second direction (Y) intersecting the first direction (X), and that are formed at the principal surface (3) so as to penetrate through the source region (22) and the body region (21), a trench source structure (33) that is formed at the principal surface (3) so as to penetrate through the source region (22) and the body region (21) between two of the trench gate structures (23) that are adjacent and that has one end portion on one side in the first direction (X) and one other end portion on one other side in the first direction (X), a second-conductivity-type (p type) body connection region (51) formed in a region on one end portion side of the trench source structure (33) in the surface layer portion of the body region (21) so as to be electrically connected to the body region (21), and a first-conductivity-type (n type) source connection region (52) formed in a region on one other end portion side of the trench source structure (33) in the surface layer portion of the body region (21) so as to be electrically connected to the source region (22).

[B2] The SiC semiconductor device according to B1, wherein the source connection region (52) faces the body connection region (51) in the first direction (X) with the trench source structure (33) between the source connection region (52) and the body connection region (51).

[B3] The SiC semiconductor device according to B1 or B2, wherein the body connection region (51) is formed at a distance from a plurality of the trench gate structures (23).

[B4] The SiC semiconductor device according to any one of B1 to B3, wherein the body connection region (51) has an impurity concentration exceeding an impurity concentration of the body region (21).

[B5] The SiC semiconductor device according to any one of B1 to B4, wherein the source region (22) has an impurity concentration exceeding an impurity concentration of the drift region (7), and the source connection region (52) has an impurity concentration exceeding the impurity concentration of the drift region (7).

[B6] The SiC semiconductor device according to any one of B1 to B5, wherein the source connection region (52) is formed by using a part of the source region (22).

[B7] The SiC semiconductor device according to any one of B1 to B6, wherein the trench source structure (33) is formed in a belt shape extending in the first direction (X).

[B8] The SiC semiconductor device according to any one of B1 to B7, wherein the trench source structure (33) is formed more deeply than the trench gate structure (23).

[B9] The SiC semiconductor device according to any one of B1 to B8, wherein a plurality of the trench source structures (33) are arranged with intervals therebetween in the first direction (X) between a plurality of the trench gate structures (23), the body connection region (51) is formed in a region partitioned by two of the trench source structures (33) that are adjacent in the surface layer portion of the body region (21), and the source connection region (52) is formed in a region partitioned by two of the trench source structures (33) that are adjacent in a region differing from the body connection region (51) in the surface layer portion of the body region (21).

[B10] The SiC semiconductor device according to B9, wherein a plurality of the trench gate structures (23) are arranged with first intervals (P1) therebetween in the second direction (Y), and a plurality of the trench source structures (33) are arranged with second intervals (P2) each of which is equal to or less than the first interval (P1) therebetween in the first direction (X).

[B11] The SiC semiconductor device according to B10, wherein the second interval (P2) is less than a length (L) in the first direction (X) of each of the trench source structures (33).

[B12] The SiC semiconductor device according to any one of B1 to B11, further including a second-conductivity-type (p type) trench connection region (53) formed in a region along a wall surface of the trench source structure (33) in the drift region (7) so as to be electrically connected to the body connection region (51) in the surface layer portion of the principal surface (3).

[B13] The SiC semiconductor device according to B12, wherein the trench connection region (53) has an impurity concentration exceeding an impurity concentration of the body region (21).

[B14] The SiC semiconductor device according to B12 or B13, wherein the trench connection region (53) covers a sidewall and a bottom wall of the trench source structure (33).

[B15] The SiC semiconductor device according to any one of B12 to B14, wherein the trench connection region (53) partially covers the wall surface of the trench source structure (33) so as to expose a part of the wall surface of the trench source structure (33).

[B16] The SiC semiconductor device according to any one of B12 to B15, further including a second-conductivity-type (p type) well region (54) that is formed in a region along the wall surface of the trench source structures (33) so as to cover the trench connection region (53) in the drift region (7) and that has an impurity concentration less than an impurity concentration of the trench connection region (53).

[B17] The SiC semiconductor device according to B16, wherein the well region (54) has a part that covers the trench source structure (33) with the trench connection region (53) between the part of the well region (54) and the trench source structure (33) and a part that directly covers the trench source structure (33).

[B18] The SiC semiconductor device according to any one of B1 to B17, further including a source principal surface electrode (73) that is formed on the principal surface (3) and that is electrically connected to the trench source structure (33), to the body connection region (51), and to the source connection region (52) on a line connecting the trench source structure (33), the body connection region (51), and the source connection region (52) together.

[B19] The SiC semiconductor device according to B18, further including an interlayer insulating film (60) that has one or more openings (64, 65, 66, 132) that expose the trench source structure (33), the body connection region (51), and the source connection region (52) and that covers the principal surface (3), wherein the source principal surface electrode (73) is formed on the interlayer insulating film (60), and is electrically connected to the trench source structure (33), to the body connection region (51), and to the source connection region (52) in the one or more openings (64, 65, 66, 132).

While preferred embodiments of the present invention have been described in detail, these are merely specific examples used to clarify the technical contents of the present invention and the present invention should not be interpreted as being limited to these specific examples and the scope of the present invention is to be limited by the appended claims.

### REFERENCE SIGNS LIST

1 SiC semiconductor device (semiconductor device)
2 SiC chip (semiconductor chip)
3 first principal surface
7 drift region
21 body region
22 source region
23 trench gate structure
24 mesa portion
33 trench source structure
34 segment portion
34A first segment portion
34B second segment portion
51 body connection region
52 source connection region
53 trench connection region
54 well region
73 source principal surface electrode
101 SiC semiconductor device (semiconductor device)
111 SiC semiconductor device (semiconductor device)
121 SiC semiconductor device (semiconductor device)
131 SiC semiconductor device (semiconductor device)
141 SiC semiconductor device (semiconductor device)
151 SiC semiconductor device (semiconductor device)
161 SiC semiconductor device (semiconductor device)
P1 first interval
P2 second interval
X first direction
Y second direction

1. A semiconductor device comprising:
a semiconductor chip having a principal surface;
a first-conductivity-type drift region formed at a surface layer portion of the principal surface;
a second-conductivity-type body region formed at a surface layer portion of the drift region;
a first-conductivity-type source region formed at a surface layer portion of the body region;
a plurality of trench source structures that are formed at the principal surface so as to cross the source region and the body region and so as to reach the drift region and that are arranged with intervals therebetween;
a second-conductivity-type body connection region formed in a region between two of the trench source structures that are adjacent in the surface layer portion of the body region so as to be electrically connected to the body region; and
a first-conductivity-type source connection region formed in a region between two of the trench source structures that are adjacent in a region differing from the body connection region in the surface layer portion of the body region so as to be electrically connected to the source region.

2. The semiconductor device according to claim 1, wherein the source connection region faces the body connection region in the first direction with the trench source structure between the source connection region and the body connection region.

3. The semiconductor device according to claim 1, wherein a plurality of the trench source structures are each formed in a belt shape extending in the first direction.

4. The semiconductor device according to claim 1, wherein the body connection region has an impurity concentration exceeding an impurity concentration of the body region.

5. The semiconductor device according to claim 1, wherein the source region has an impurity concentration exceeding an impurity concentration of the drift region, and
the source connection region has an impurity concentration exceeding the impurity concentration of the drift region.

6. The semiconductor device according to claim 1, wherein the source connection region is formed by using a part of the source region.

7. The semiconductor device according to claim 1, wherein a plurality of the body connection regions are formed, and
a plurality of the source connection regions are formed.

8. The semiconductor device according to claim 7, wherein a plurality of the source connection regions are formed alternately with a plurality of the body connection regions along the first direction.

9. The semiconductor device according to claim 1, further comprising a plurality of trench gate structures that are formed at the principal surface so as to cross the source region and the body region and so as to reach the drift region, each of which extends in the first direction, and that are arranged at the principal surface with intervals therebetween in a second direction intersecting the first direction,
wherein a plurality of the trench source structures are arranged with intervals therebetween in the first direction between two of the trench gate structures that are adjacent.

10. The semiconductor device according to claim 9, wherein the body connection region is formed at a distance from a plurality of the trench gate structures.

11. The semiconductor device according to claim 9, wherein each of the trench source structures is formed more deeply than each of the trench gate structures.

12. The semiconductor device according to claim 9, wherein a plurality of the trench gate structures partition a plurality of mesa portions each of which extends in the first direction at the principal surface,
a plurality of the trench source structures partition a plurality of segment portions constituted of a part of the mesa portion in the mesa portion,
the body connection region is formed in the segment portion, and
the source connection region is formed in the segment portion differing from the segment portion in which the body connection region is formed.

13. The semiconductor device according to claim 12, wherein a plurality of the segment portions include a plurality of first segment portions and a plurality of second segment portions alternately arranged along the first direction,
a plurality of the body connection regions are formed in a plurality of the first segment portions, and
a plurality of the source connection regions are formed in a plurality of the second segment portions.

14. The semiconductor device according to claim 9, wherein a plurality of the trench gate structures are arranged with first intervals therebetween in the second direction, and
a plurality of the trench source structures are arranged with second intervals each of which is less than the first interval therebetween in the first direction.

15. The semiconductor device according to claim 1, further comprising a second-conductivity-type trench connection region led out from the body connection region to a region along a wall surface of at least one of the trench source structures in the surface layer portion of the drift region.

16. The semiconductor device according to claim 15, wherein the trench connection region covers a sidewall and a bottom wall of the trench source structure.

17. The semiconductor device according to claim 15, wherein the trench connection region partially covers the wall surface of the trench source structure so as to expose a part of the wall surface of the trench source structure.

18. The semiconductor device according to claim 15, further comprising a second-conductivity-type well region that is formed in a region along the wall surface of at least one of the trench source structures so as to cover the trench connection region in the surface layer portion of the drift region and that is lower in impurity concentration than the body connection region.

19. The semiconductor device according to claim 18, wherein the well region has a part that covers the trench source structure with the trench connection region between the part of the well region and the trench source structure and a part that directly covers the trench source structure.

20. The semiconductor device according to claim 1, further comprising a source principal surface electrode that is formed on the principal surface and that is electrically connected to the trench source structure, to the body connection region, and to the source connection region on a line connecting the trench source structure, the body connection region, and the source connection region together.
